(19) United States
(12) Patent Application Publication
(10) Pub. No.: US 2017/0154682 A1
(43) Pub. Date: Jun. 1, 2017

(54) MEMORY SYSTEM AND OPERATION METHOD THEREOF

(71) Applicants: SK hynix Inc., Gyeonggi-do (KR); Korea Advanced Institute of Science and Technology, Daejeon (KR)

(72) Inventors: Jaekyun MOON, Daejeon (KR); Jaehyeong NO, Daejeon (KR)

(21) Appl. No.: 15/099,369

(22) Filed: Apr. 14, 2016

(30) Foreign Application Priority Data
Dec. 1, 2015 (KR) 10-2015-0169936

(51) Int. Cl. G11C 16/26

(52) U.S. Cl. CPC G11C 16/26

(57) ABSTRACT

A memory system includes: a memory apparatus suitable for providing read data; and a plurality of equalizing units respectively suitable for rotationally performing equalization operations to the read data in different directions in a two-dimensional inter-symbol interference (2D ISI) mask, wherein the 2D ISI mask comprises the read data of a victim cell and a plurality of interference data, which exert interferential influence on the read data, of interference cells neighboring the victim cell, and wherein a first one of the equalizing units generates a first equalization information by performing the equalization operation to the read data in a first one of the different directions based on a third equalization information received from a third one of the equalizing units, and provides the generated first equalization information to a second one of the equalizing units.

### CROSS-REFERENCE TO RELATED APPLICATIONS

This application claims priority under 35 U.S.C, §119 to Korean Patent Application No, 10-2015-0169936 filed on Dec. 1, 2015 in the Korean Intellectual Property Office, which is incorporated herein by reference in its entirety.

### BACKGROUND

1. Field

Various embodiments of the present invention relate generally to a memory system and, more particularly, to a memory system capable of effectively cancelling an interference signal through a plurality of equalizers.

2. Description of t he Related Art

As data storage density of semiconductor memory devices increases, inter-symbol interference (ISI) may also increase. ISI generally occurs as a result of a discontinuity of at least one of a channel impedance, linear amplification, and phase distortion.

Particularly, a plurality of neighboring memory cells, which are adjacent to a memory cell which stores data, may interfere with the stored data of the memory cell thus damaging the stored data. This phenomenon is referred to as a two dimensional (2D) ISI.

It is generally harder to control 2D ISI in a flash memory device, or a solid state drive (SSD) device because such devices have greater data storage density obtained by narrowing the distances between memory cells or tracks. For this reason, such devices typically employ an equalizer for cancelling 2D ISI.

An equalizer may reduce 2D-ISI caused by channel distortion. However, generally, waveforms of output signals of an equalizer depend on the compensation size of the equalizer.

Because of continuing demand for higher density memory devices, there is a need for further reducing 2D ISI and for optimizing the compensation size of an equalizer used in memory devices.

### SUMMARY

Various embodiments of the present invention are directed to an improved equalizer which is suitable for cancelling 2D ISI.

According to an embodiment of the present invention, a memory system may include: a memory apparatus suitable for providing read data; and a plurality of equalizing units respectively suitable for performing an equalization operation to the read data in a plurality of different directions in a two-dimensional inter-symbol interference (2D ISI) mask, wherein the 2D ISI mask comprises the read data of a victim cell and a plurality of interference data of interference cells neighboring the victim cell, which exert interferential influence on the read data of the victim cell. The plurality of equalizing units may perform an equalization operation to the read data in a rotational manner. A first one of the equalizing units may generate a first equalization information by performing the equalization operation to the read data in a first direction among the plurality of different directions based on a third equalization information received from a third equalizing unit, and provides the generated first equalization information to a second equalizing unit. The first equalizing unit may output an off-track-interference-removed data by removing an off-track interference data from the read data based on the third equalization information, and The off-track interference data may be the interference data of the interference cells disposed aside from the first direction. The first equalizing unit may generate the first equalization information by removing a linear equalization interference data from the off-track-interference-removed data based on the third equalization information. The linear equalization interference data may be the interference data of the interference cells disposed in line with the first direction. An equalization information of each of the equalizing units may include an equalized data of the read data and further may comprise a decoder suitable for performing a decoding operation to the equalized data received from last one of the equalizing units, which lastly performs the equalization operation to the read data. An equalization information of each of the equalizing units may include a priori information and a priori soft decision value, and the priori information may be an equalized data of the read data The first equalizing unit may output an off-track-interference-removed data by removing an off-track interference data from the read data based on the priori soft decision value included in the third equalization information, and the off-track interference data may be the interference data of the interference cells disposed aside from the first direction. The first equalizing unit may generate the priori information and the priori soft decision value of the first equalization information by removing a linear equalization interference data from the off-track-interference-removed data based on the priori information and the priori soft decision value included the third equalization information, and herein the linear equalization interference data may be the interference data of the interference cells disposed in line with the first direction. The different directions may include a horizontal direction, a first diagonal direction, and a second diagonal direction vertically or horizontally reversed to the first diagonal direction.

According to an embodiment o the present invention, an operation method of a memory system including a memory apparatus may include: receiving read data from the memory apparatus; and rotationally performing at least first to third equalization operations to the read data in different directions in a two-dimensional inter-symbol interference (2D ISI) mask, wherein the 2D ISI mask comprises the read data of a victim cell and a plurality of interference data, which exert interferential influence on the read data, of interference cells neighboring the victim cell, wherein the first equalization operation is performed in a first one of the different directions based on a third equalization information generated by the performing of the third equalization operation thereby generating a first equalization Information, and wherein the generated first equalization information by the performing of the first equalization operation is used in the performing of the second equalization operation.

The performing of the first equalization operation may include outputting an off-track-interference-removed data by removing an off-track interference data from the read data based on the third equalization information, and the off-track interference data may be the interference data of the interference cells disposed aside from the first direction. The first equalization operation may include generating the first equalization information by removing a linear equalization interference data from the off-track-interference-removed data based on the third equalization information and the linear equalization interference data may be the interference data of the interference cells disposed in line with the first direction. An equalization information as a result of each of the at least first to third equalization operations may include an equalized data of the read data, and may comprise performing a decoding operation to the equalized data, which is a result of last one of the at least first to third equalization operation, which is lastly performed to the read data. An equalization information as a result of each of the at least first to third equalization operations may include a priori information and a priori soft decision value, and the priori information may be an equalized data of the read data. The performing of the first equalization operation may include outputting an off-track-interference-removed data by removing an off-track interference data from the read data based on the priori soft decision value included in the third equalization information, and the off-track interference data may be the interference data of the interference cells disposed aside from the first direction. The first equalization operation may include generating the first equalization information by removing a linear equalization interference data from the off-track-interference-removed data based on the priori information and the priori soft decision value included the third equalization information, and the linear equalization interference data may be the interference data of the interference cells disposed in line with the first direction. The different directions may include a horizontal direction, a first diagonal direction, and a second diagonal direction vertically or horizontally reversed to the first diagonal direction.

According to an embodiment of the present invention, a memory system may include: a memory apparatus suitable for storing read data and write data requested by a host; and a controller suitable for providing the read data to the host and providing the write data to the memory apparatus in response to a request of the host, and including a plurality of equalizing units including: a first equalizing unit suitable for outputting a first data by performing a first equalization operation to the read data provided from the memory apparatus in response to a read command provided from the host, a second equalizing unit suitable for outputting a second data by performing a second equalization operation to the read data, and a third equalizing unit suitable for outputting a third data by performing a third equalization operation to the read data.

According to an embodiment of the present invention, the 2D ISI may be reduced with lower complexity by repeating equalization operation a predetermined number of times with an equalizer including a plurality of equalizing units.

According to an embodiment of the present invention, the 2D ISI may be reduced with lower complexity by cancelling an interference signal of each of plural directions in a 2D ISI mask through an equalizer including a plurality of equalizing units of different single dimensional directions.

According to an embodiment of the present invention, the bit-error rate may be reduced by repeating equalization operation a predetermined number of times with an equalizer including a plurality of equalizing units of different single dimensional directions before performing data decoding operation.

### BRIEF DESCRIPTION OF THE DRAWINGS

FIG. 1 is a block diagram schematically illustrating a semiconductor memory system according to an embodiment of the present invention

FIG. 2 is a block diagram schematically illustrating a data processing operation in a memory system according to an embodiment of the present invention.

FIGS. 3A to 3C are diagrams illustrating a plurality of memory cells in accordance with an embodiment of the present invention.

FIG. 4 is a diagram illustrating a weight value vector h of a two-dimensional inter-symbol interference mask.

FIG. 5 is a block diagram schematically illustrating an equalizer shown in FIG. 2.

FIG. 6A is a block diagram schematically illustrating a first equalizing unit shown in FIG. 5.

FIG. 6B is a block diagram schematically illustrating a second equalizing unit shown in FIG. 5.

FIG. 6C is a block diagram schematically illustrating a third equalizing unit shown in FIG, 5,

FIG. 7 is a flowchart illustrating an equalization operation of the first equalizing unit according to an embodiment of the present invention.

FIG. 8 is a flowchart illustrating an equalization operation of the second equalizing unit according to an embodiment of the present invention.

FIG. 9 is a flowchart illustrating an equalization operation of the third equalizing unit according to an embodiment of the present invention,

FIGS. 10 to 17 are diagrams schematically illustrating a three-dimensional (3D) nonvolatile memory device according to an embodiment of the present invention.

FIG. 18 is a block diagram schematically illustrating an electronic device including a semiconductor memory system according to an embodiment of the present invention.

FIG. 19 is a block diagram schematically illustrating an electronic device including a semiconductor memory system according to an embodiment of the present invention.

FIG. 20 is a block diagram schematically illustrating an electronic device including a semiconductor memory system according to an embodiment of the present invention.

### DETAILED DESCRIPTION

Various embodiments will be described below in more detail with reference to the accompanying drawings. The present invention may, however, be embodied in different forms and should not be construed as being limited to the embodiments set forth herein. Rather, these embodiments are provided so that this disclosure will be thorough and complete and will fully convey the present invention to those skilled in the art. The drawings are not necessarily to scale and in some instances, proportions may have been exaggerated in order to clearly illustrate features of the embodiments. Throughout the disclosure, reference numerals correspond directly to the like parts in the various figures and embodiments of the present invention.

It is also noted that in this specification, “connected/coupled” refers to one feature not only directly coupling another feature but also indirectly coupling another feature through an intermediate feature. In addition, a singular form may include a plural form as long as it is not specifically mentioned otherwise in a sentence. It should be readily understood that the meaning of and “over” in the present invention should be interpreted in the broadest manner so that “on” means not only directly on but also “on” something with an intermediate feature(s) or a layer(s) therebetween and that “over” means not only directly on top but also on top of something with an intermediate feature therebetween. When a first feature or layer is referred to as being “on” a second feature or layer or “on” a substrate, it not only refers to a case where the first layer is formed directly on the second feature or layer or the substrate but also a case where a third layer exists between the first feature or layer and the second feature or layer or the substrate.

It will be further understood that, although the terms “first”, “second third” and so on may be used herein to describe various features, these features are not limited by these terms. These terms are used to distinguish one feature from another feature. Thus, a first feature described below could also be termed as a second or third feature without departing from the spirit and scope of the present invention. The terminology used herein is for the purpose of describing particular embodiments only and is not intended to be limiting of the present invention,

It will be further understood that the terms “comprises”, “comprising”, “includes”, and “including” when used in this specification, specify the presence of the stated features but do not preclude the presence or addition of one or more other features. As used herein, the term “and/or” includes any and all combinations of one or more of the associated listed items.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present invention. The present invention may be practiced without some or al of these specific details. In other instances, well-known process structures and/or processes have not been described in detail in order not to unnecessarily obscure the present invention.

Hereinafter, the various embodiments of the present invention will be described in details with reference to attached drawings.

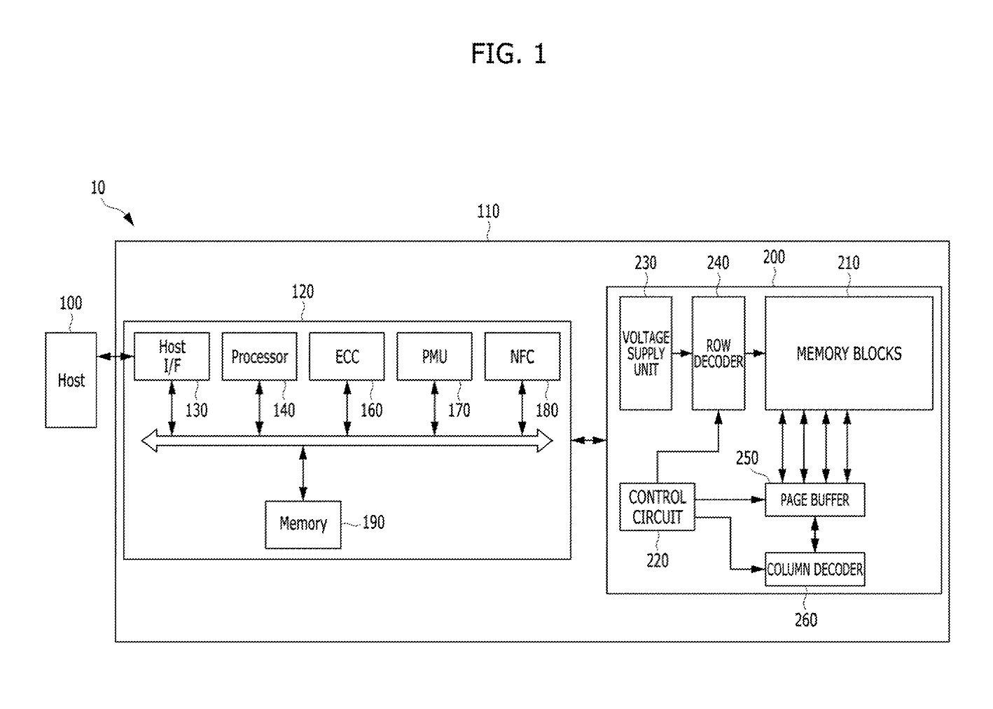

Referring now to FIG. 1 a semiconductor memory system 110 is provided, according to an embodiment of the present invention.

According to the embodiment of FIG. 1, a data processing system 10 may include a host 100 and the memory system 110.

The host 100 may include, for example, a portable electronic device, such as, for example, a mobile phone, an MP3 player, and a laptop computer or an electronic device, such as, for example, a desktop computer, a game player, a TV, a projector, and the like.

The memory system 110 may operate in response to a request of the host 100. For example, the memory system 110 may store data to be accessed by the host 100. Also, for example, the memory device 200 may store the data received from the host 100 through a write operation, and provide stored data to the host 100 through a read operation.

The memory system 110 may be used as a main memory system or an auxiliary memory system of the host 100. The memory system 110 may be implemented with any one of various kinds of storage devices, according to the protocol of a host interface to be electrically coupled with the host 100. The memory system 110 may be implemented with any one of various kinds of storage devices, such as for example, a solid-state drive (SSD), a multimedia card (MMC), an embedded MMC (eMMC), a reduced-size MMC (RS-MMC) and a micro-MMC a secure digital (SD) card, a mini SD card, a micro SD card, a universal serial bus (USB) storage device, a universal flash storage (UFS) device, a compact flash (CF) card, a smart media (SM) card, a memory stick, and the like.

A memory system 110 may include a memory device 200 which may store data to be accessed by the host 100, and a controller 120 which may control storage of data in the memory device 200.

The memory device 200 may be implemented with a volatile memory device, such as, for example, a dynamic random access memory (DRAM) and a static random access memory (SRAM) or a nonvolatile memory device, such as, for example, a read only memory (ROM), a mask ROM (MROM), a programmable ROM (PROM), an erasable programmable ROM (EPROM), an electrically erasable programmable ROM (EEPROM), a ferroelectric random access memory (FRAM), phase change RAM (PRAM), a magnetoresistive RAM (MRAM) a resistive RAM (RRAM), and the like. One or more memory devices 200 may be used as storage devices.

When implemented as a non-volatile memory device, the memory device 200 may retain stored data even when power supply is interrupted.

The controller 120 and the memory device 200 may be integrated into a single semiconductor device and configured as a memory card. For instance, the controller 120 and the memory device 200 may be integrated into a single semiconductor device configured as a sol id state drive (SSD). When the memory system 110 is used as a SSD, the operation speed of the host 100 that is electrically coupled with the memory system 110 may be significantly increased.

The controller 120 and the memory device 200 may be integrated into a single semiconductor device configured as a memory card, such as, for example, a personal computer memory card international association (PCMCIA), a compact flash (CF) card, a smart media (SM) card (SMC), a memory stick, a multimedia card (MMC), a reduced-size (RS)MMC, a micro-MMC, a secure digital (SD) card, a mini-SD SD card, a micro-SD card, a secure digital high capacity (SDHC), and a universal flash storage (UFS) device.

In an embodiment, the memory system 110 may be or configure a computer, an ultra-mobile PC (UMPC), a workstation, net-book, a personal digital assistant (PDA), a portable computer, web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage configuring a data center, a device capable of transmitting and receiving, information under a wireless environment, one of various electronic devices configuring a home network, one of various electronic devices configuring a computer network, one of various electronic devices configuring a telematics network, an RFID device, one of various component features configuring a computing system, and the like.

According to the embodiment of FIG.. 1, the memory device 200 of the memory system 110 may include a plurality of memory blocks 210, a control circuit 220, a voltage supply unit 230, a row decoder 240, a page buffer 250, and a column decoder 260. The memory device 200 may be a nonvolatile memory device, for example a flash memory device. The memory device may be a flash memory device having a 3-dimensional (3D) stacked structure.

Each of the memory blocks 210 may include a plurality of pages. Each of the pages may include a plurality of memory cells.. The memory cells of each page may be coupled electrically to a single word line among a plurality of word lines (WL).

The control circuit 220 may control various operations of the memory device 200, such as, for example, at least one of a program erase, and read operations.

The voltage supply unit 230 may provide word line voltages, for example, a program voltage, a read voltage, and a pass voltage, to the respective word lines according to an operation mode, and may provide a voltage to a bulk, for example, a well region of the memory device, in which the memory cells are formed. A voltage generating operation of the voltage supply circuit 230 may be performed under control of the control logic 220. The voltage supply unit 230 may generate a plurality of variable read voltages for generation of a plurality of read data.

The row decoder 240 may select one of the memory blocks or sectors of the memory cell array 210, and may select one or more word lines among the word lines of the selected memory block under the control of the control logic 220. The row decoder 240 may provide a word line voltage generated from the voltage supply circuit 230 to the one or more selected word lines and may provide another voltage for one or more non-selected word lines, all under the control of the control logic 220 for performing a command received from the host, such as, for example, at least one of a read, write, or erase operations.

For example, during a program operation, the page buffer 250 may operate as a write driver for driving respective bit lines according to data to be stored in the memory block 210. During a program operation, the page buffer 250 may receive the data to be written in the memory block. 210 from a buffer (not illustrated) and may drive the respective bit lines according to the input data. The page buffer 250 may be formed of a plurality of page buffers (PB) 251 corresponding to respective columns or bit lines, or more particularly to respective column pairs or bit line pairs. For example, a plurality of latches may be included in each of the plurality of page buffers 251.

The controller 120 of the memory system 110 may control the memory device 200 in response to a request from the host 100. The controller 120 may provide the data read from the memory device 200 to the host 100. The controller 120 may also store data received from the host 100 into the memory device 200. To this end, the controller 120 may control the overall operations of the memory device 200, including at least one of a read, write (program) and erase operations.

According to the embodiment of FIG. 1, the controller 120 may include a host interface unit 130, a processor 140, an error correction code (ECC) unit 160, a power management unit (PMU) 170, a NAND flash controller (NFC) 180, and a memory 190.

The host interface 130 may process a command and data from the host 100 and may communicate with the host 100 through at least one of various interface protocols, such as, for example, a universal serial bus (USB), a multi-media card (MMC), a peripheral component interconnect express (PCI-E), a serial-attached SCSI (SAS), a serial advanced technology attachment (SATA), a parallel advanced technology attachment (PATH), a small computer system interface (SCSI), an enhanced small disk interface (ESDI), an integrated drive electronics (IDE), and the like.

The ECC unit 160 may detect and correct errors in data read from the memory device 200 during a read operation. For example, the ECC unit 160 may perform the ECC decoding on data read from the memory device 200, determine whether the ECC decoding is successful, output an instruction signal according to the determination result, and correct error bits of the read data using parity bits generated during the ECC encoding. For example, the ECC unit 160 may not correct error bits when the number of the error bits is greater than or equal to a threshold number of correctable error bits, and may output a fail signal indicating a failure in correcting the error bits.

The ECC unit 160 may perform an error correction operation based on any suitable well known schemes, including coded modulation, such as, for example, a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a block coded modulation (BCM), and the like. The ECC unit 160 may include any circuits, systems or devices suitable for performing the error correction operation.

The PMU 170 may provide and manage the power needs for the controller 120, for example, the power supplied for the component features included in the controller 120. The PMU 170 may include any circuits, systems or devices suitable for providing and modulating the power supply to the various components of the controller 120.

The NFC 180 may serve as a memory interface between the controller 120 and the memory device 200 to allow the controller 120 to control the memory device 200 in response to a request received from the host 100 For example, the NFC 180 may generate control signals for the memory device 200 and process data under the control of the processor 140 when the memory device 150 is a flash memory and, in particular, when the memory device 150 is a NAND flash memory.

The memory 190 may serve as a working memory of the memory system 110 and the controller 120, and store data for driving the memory system 110 and the controller 120. The controller 120 may control the memory device 200 in response to a request received from the host 100. For example, the controller 120 may provide the data read from the memory device 200 to the host 100, and may store the data received from the host 100 in the memory device 200. When the controller 120 controls the operations of the memory device 200, the memory 190 may store data used by the controller 120 and the memory device 200 for such operations as read, write, program and erase operations.

The memory 190 may be implemented with a volatile memory, such as, for example, a static random access memory (SRAM), a dynamic random access memory (DRAM), and the like. As described above, the memory 190 may store data used by the host 100 and the memory device 200, for example, for a write and/or read operations. For storing data, the memory 190 may include a program memory, a data memory, a write buffer, a read buffer, a map buffer, and the like,

Additionally, the memory 190 may store data for operations between the ECC unit 160 and the processor 140, such as, for example, data that is read during a read operation. That is, the memory 190 may store data read from the semiconductor memory device 200. The data may include, for example, user data, parity data and status data. The status data may include information of which cycling group is applied to the memory block 210 of the semiconductor memory device 200 during a program operation.

The processor 140 may control one or more of the general operations of the memory system 110, including, for example, a write operation or a read operation for the memory device 200, in response to a write request or a read request from the host 100. The processor 140 may drive firmware, which is referred to as a flash translation layer (FTL), to control the general operations of the memory system 110. The processor 140 may be implemented with any suitable circuits or devices including, for example, microprocessor, a central processing unit (CPU), and the like.

Other well-known circuits may also be included in the processor 140 which are not shown in FIG. 1 as may be needed. For example, a management unit (not shown) may be included in the processor 140 for performing a bad block management operation of the memory device 200. The management unit may find bad memory blocks included in the memory device 200, which are in unsatisfactory condition for further use, and perform a bad block management operation on the bad memory blocks, according to one of a plurality of well-known schemes. When the memory device 200 is a flash memory, for example, a NAND flash memory, a program failure may occur during the write operation, for example, during the program operation, due to the characteristics of a NAND logic function. For example, during a bad block management, the data of a program-failed memory block (bad memory block) may be programmed into a new memory block. Generally, bad blocks due to a program fail may seriously deteriorate the utilization efficiency of the memory device 200 having a 3D stack structure and the reliability of the memory system 110, and thus reliable bad block management may be required.

According to an embodiment of the present invention, each of a plurality of equalizing units may perform an equalization operation to a read data yₖ read out from each of the plurality of memory blocks in the memory apparatus 200 in a corresponding direction in a 2D ISI mask, and thus the inter-symbol interference (ISI) and the additive white gaussian noise (AWGN), which are included in the read data may be effectively cancelled. Accordingly, during an error correction operation, an original data xₖ may be restored through a decoding operation with a lower error rate than existing schemes.

The present invention provides an equalizer and an equalization operation of the equalizer that are suitable for more effectively cancelling ISI and AWN included in read data yₖ. Although the following disclosure exemplifies the controller 120 performing the equalization operation it the memory system as an example, we note that the processor 140 of the controller 120 may also perform the equalization operation.

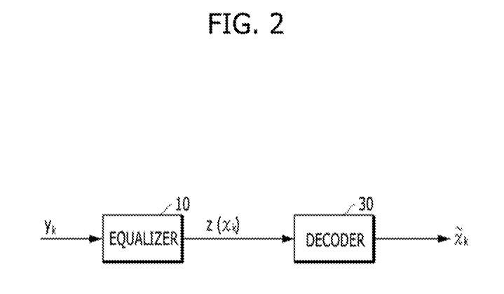

FIG. 2 is a block diagram schematically illustrating a data processing operation in the memory system 110 according to an embodiment of the present invention.

Referring to FIG. 2, the controller 120 may receive the read data yₖ, which is read out from the memory apparatus 200, and restore the original data xₖ, which is stored in the memory apparatus 200, from the read data yₖ by performing an equalization operation followed by a decoding operation to the read data yₖ. To this end, the controller 120 may include an equalizer 10 and a decoder 30, as illustrated in FIG. 2.

Accordingly, the equalizer 10 may receive the read data yₖ from the memory apparatus 200 through a channel, and perform an equalization operation to the read data yₖ. The equalizer 10 may cancel interference data in the read data yₖ through the equalization operation to the read data yₖ.

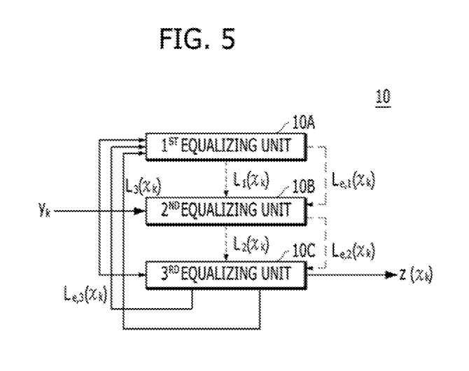

The equalizer 10 may include a plurality of equalizing units 10A to 10C (as illustrated in FIG. 5). The equalizer 10 may cancel interference data in the read data by repeating the equalization operation to the read data yₖ a predetermined number of times through the plurality of equalizing units 10A to 10C. The equalizer 10 may also perform equalization operations in different directions in a 2D ISI mask, as will be described later in more detail. For example, the equalizer 10 may perform equalization operations in different directions in a 2D ISI mask through the use of the plurality of equalizing units 10A to 10C.

The read data yₖ may be the original data xₖ, to which the 2D ISI signal and the AWGN are added, and may be represented by the following equation 1.

$${y}_{k} = {\sum }_{i = 0}^{i} {h}_{i} {x}_{k - i + t / 2} + {n}_{k} \qquad [ Equation 1 ]$$

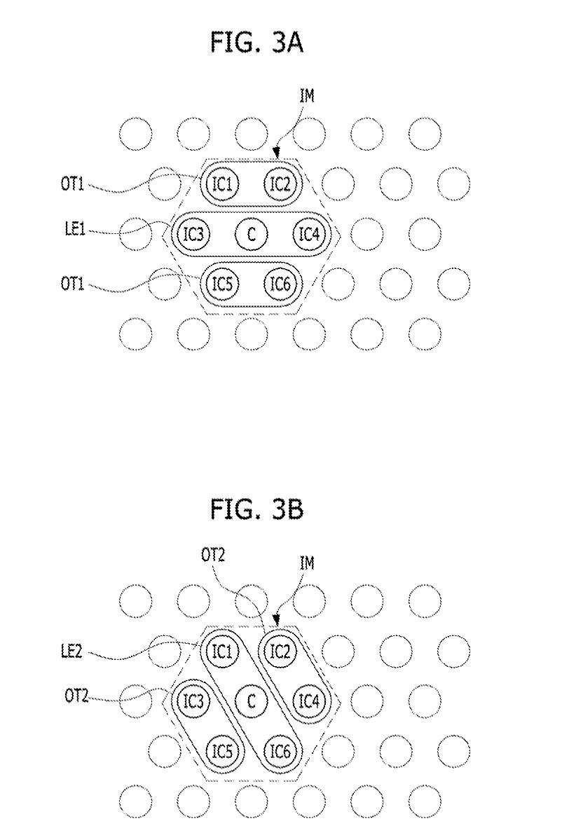

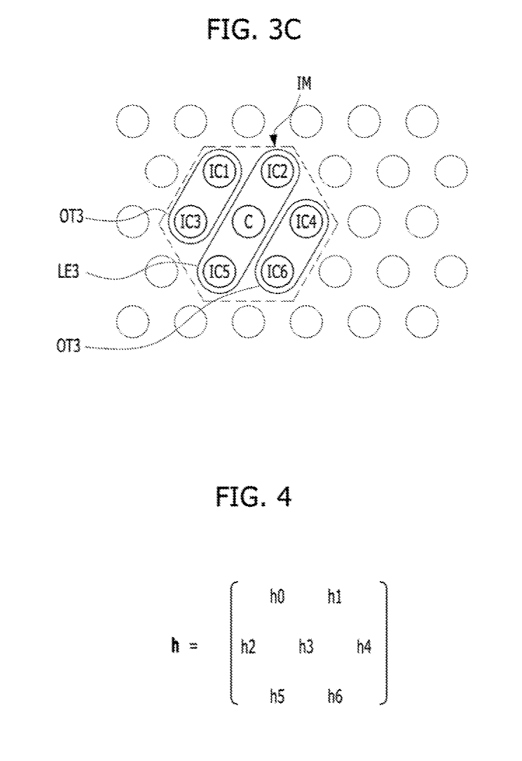

In equation 1, denotation “xₖ” represents the original data stored in the memory apparatus 200. In equation 1, denotation “x_{k-i+1/2}” represents a plurality of memory cells included in a 2D ISI mask. The plurality of memory cells included in the 2D ISI mask may include a victim memory cell that the original data xₖ is stored in, and a plurality of interference memory cells exerting interferential influence on the victim memory cell. In equation 1, denotation “l” represents a size of the 2D ISI mask. The mask size may be determined according to a number of the plurality of interference memory cells exerting interferential influence on the victim memory cell, and disposed around the victim memory cell. In other words the mask size of the 2D ISI is determined based on the interference memory cells which may be exerting interferential influence on the victim memory cell. In equation 1, denotation “h₁” represents a channel weighted value of the 2D ISI to the plurality of memory cells included in the 2D ISI mask. In equation 1, denotation “nₖ” represents a vector of the AWGN in which average of each feature is zero (0) and variance of each feature is “σₙ²”. The channel of the 2D ISI to the plurality of memory cells and the weighted vector thereof will be further described with reference to FIGS. 3A to 3C and 4.

FIGS. 3A to 3C are diagrams illustrating a plurality of neighboring memory cells in accordance with an embodiment of the present invention.

More specifically, FIGS. 3A to 3C illustrate a plurality of memory cells for the first, second and third equalizing units 10A, 10B, and 10C. FIGS. 3A to 3C illustrate the channel mask of the 2D ISI in the plurality of memory cells.

Referring to FIGS. 3A to 3C, we have realized, that it may be more effective to form the 2D ISI mask with a plurality of memory cells by analyzing any memory cells exerting interferential influence on the victim memory cell. For example, seven (7) memory cells may form the hexagonal mask (illustrated as “IM” in the figure) of the 2D ISI.

For example, the memory cells of the 2D ISI mask may include the victim memory cell (illustrated as “C” in the figure) and a plurality of interference memory cells (illustrated as “IC1” to “IC6” in the figure) surrounding the victim cell “C”. The plurality of interference memory cells exert interferential influence on the victim memory cell “C”. In the illustrated example, the plurality of interference memory cells include first to sixth interference memory cells IC1 to IC6. The first to sixth interference memory cells IC1 to IC6 may be respectively storing first to sixth interference data xₖ₋ₚ,xₖ₋ₚ₊₁,xₖ₋₁,xₖ₊₁,xₖ₊ₚ₋₁,xₖ₊ₚ. The first to sixth interference data xₖ₋ₚ,xₖ₋ₚ₊₁,xₖ₋₁,xₖ₊₁,xₖ₊ₚ₋₁,xₖ₊ₚ respectively stored in the first to sixth interference memory cells IC1 to IC6 may exert interferential influence on the original data xₖ stored in the victim memory cell “C”. In denotations of the first to sixth of interference data xₖ₋ₚ,xₖ₋ₚ₊₁,xₖ₋₁,xₖ₊₁,xₖ₊ₚ₋₁,xₖ₊ₚ, denotation “p” represents a length of each column of 2D memory cell array.

The plurality of interference memory cells may be divided into first to third interference memory cell groups according to a direction for the equalization operation. The equalization operation may be performed to the first to third interference memory cell groups in first to third directions, respectively. For example, the first direction may be a horizontal direction, the second direction may be a first diagonal direction, and the third direction may be a second diagonal direction, which is vertically or horizontally reversed to the first diagonal direction. The first to third interference memory cell groups may store first to third interference data groups, respectively.

According to the embodiment of FIG. 3A, the first interference data group may include a first off-track interference data OT1 and a first linear equalization interference data LE1. The first off-track interference data OT1 may be stored in the first, second, fifth and sixth interference memory cells IC1, IC2, IC5 and IC6 of a plurality of first off-track regions OT1. For example, the first off-track interference data stored in the memory cells of the plurality of first off-track regions OT1 may include the first, second, fifth and sixth interference data. The first linear equalization interference data LE1 may be stored in the third and fourth interference memory cells IC3 and IC4 of a first linear equalization region LE1. For example, the first linear equalization interference data stored in the memory cells of the first linear equalization region LE1 may include the third and fourth interference data.

According to the embodiment of FIG. 3B, the second interference data group may include a second off-track interference data and a second linear equalization interference data. The second off-track interference data may be stored in the second to fifth interference memory cells IC2 to IC5 of a plurality of second off-track regions OT2. For example, the second off-track interference data stored in the memory cells of the plurality of second off-track regions OT2 may include the second to fifth interference data. The second linear equalization interference data may be stored in the first and sixth interference memory cells IC1 and IC6 of a second linear equalization region LE2. For example, the second linear equalization interference data stored in the memory cells of the second linear equalization region LE2 may include the fir t interference data and the sixth interference data.

According to the embodiment of FIG. 3C, the third interference data group may include a third off-track interference data and a third linear equalization interference data. The third off-track interference data may be stored in the first, third, fourth and sixth interference memory cells IC1, IC3, IC4 and IC6 of a plurality of third off-track regions OT3. For example, the third off-track interference data stored in the memory cells of the plurality of third off-track regions OT3 may include the first, third, fourth and sixth interference data. The third linear equalization interference data may be stored in the second and fifth interference memory cells IC2 and IC5 of a third linear equalization region LE3. For example, the third linear equalization interference data stored in the memory cells of the third linear equalization region LE3 may include the second and fifth interference data.

FIG. 4 is a diagram illustrating a weight value vector h of the 2D ISI mask.

Referring to FIG. 4, the 2D ISI mask may include a plurality of weight values corresponding to the original data xₖ stored in the victim memory cell “C” and the plurality of interference data stored in the first to sixth interference memory cells IC1 to IC6. For example, when the size of the 2D ISI mask is six (6), a weight value vector of the 2D ISI mask may include first to sixth weight values h₀ to h₆.

As defined in equation 1, the read data yₖ may be obtained through summation of respective multiplication of the original data xₖ stored in the victim memory cell “C” and the plurality of interference data stored in the first to sixth interference memory cells IC1 to IC6, which forms the 2D ISI mask, to corresponding first to sixth weight values h₀ to h₆ and through addition of the AWGN to the result of the summation.

Referring back to FIG. 2, the equalizer 10 may cancel the 2D ISI included in the read data yₖ by performing the equalization operation to the read data yₖ in each of plural directions (e.g., the horizontal and first and second diagonal directions) in the 2D ISI mask. The equalizer 10 may provide an interference-cancelled data z(xₖ) which is a resultant signal of the equalization operation to the read data yₖ, to the decoder 30.

The decoder 30 may perform the error correction operation to the interference-cancelled data z(xₖ) received from the equalizer 10. The decoder 30 may generate a restored original data \tilde{x}ₖ by correcting an error included in the interference-cancelled data z(xₖ).

FIG. 5 is a block diagram schematically illustrating the equalizer 10 shown in FIG. 2, according to an embodiment of the invention.

The equalizer 10 may include the first to third equalizing units 10A to 10C sequentially performing the equalization operation.

The first equalizing unit 10A may generate a first outer information L_{o,1}(xₖ) and a first soft decision value L₁(xₖ) through a third outer information L_{o,3}(xₖ) and a third soft decision value L₃(xₖ) received from the third equalizing unit 10C, and provide the first outer information L_{o,1}(xₖ) and the first soft decision value L₁(xₖ) to the second equalizing unit 10B.

The second equalizing unit 10B may generate a second outer information L_{o,2}(xₖ) and a second soft decision value L₂(xₖ) through the first outer information L_{o,1}(zₖ) and the first soft decision value L₁(xₖ) received from the first equalizing unit 10A, and provide the second outer information L_{o,2}(xₖ) and the second soft decision value L₂(xₖ) to the third equalizing unit 10C.

The third equalizing unit 10C may generate a third outer information L_{o,3}(xₖ) and a third soft decision value L₃(xₖ) through the second outer information L_{o,2}(xₖ) and the second soft decision value L₂(xₖ) received from the second equalizing unit 10B, and provide the third outer information L_{o,3}(xₖ) and the third soft decision value to the first equalizing unit 10A.

The first equalizing unit 10A, the second equalizing unit 10B, and the third equalizing unit 10C may perform the equalization operation in random way. The first equalizing unit 10A may generate the first outer information L_{o,1}(xₖ) and the first soft decision value L₁(xₖ) through the second outer information L_{o,2}(xₖ) and the second soft decision value L₂(xₖ) provided from the second equalizing unit 10B, and provide the first outer information L_{o,2}(x^{k}) and the first soft decision value L₁(xₖ) to the third equalizing unit 10C. The third equalizing unit 10C may generate the third outer information L_{o,3}(xₖ) and the third soft decision value L₃(xₖ) through the first outer information L_{o,1}(xₖ) and the first soft decision value L₁(xₖ) provided from the first equalizing unit 10A, and provide the third outer information L_{o,3}(xₖ) and the third soft decision value L₃(xₖ) to the second equalizing unit 10B. The second equalizing unit 10B may generate the second outer information L_{o,2}(xₖ) and the second soft decision value L₂(xₖ) through the third outer information L_{o,3}(xₖ) and the third soft decision value L₃(xₖ) provided from the third equalizing unit 10C, and provide the second outer information L_{o,2}(xₖ) and the second soft decision value L₂(xₖ) to the first equalizing unit 10A.

Hereinafter, disclosed will be the first equalizing unit 10A, the second equalizing unit 10B, and the third equalizing unit 10C sequentially performing the equalization operation to the read data yₖ. Referring to FIG. 5, the equalizer 10 may include the plurality of equalizing units 10A, 10B and 10C suitable for performing the equalization operations in different directions (e.g., the horizontal and first and second diagonal directions), respectively. For example, the first equalizing unit 10A may perform the equalization operation in the horizontal direction, the second equalizing unit 10B may perform the equalization operation in the first diagonal direction, and the third equalizing unit 10C may perform the equalization operation in the second diagonal direction. Each of the plurality of equalizing units 10A, 10B and 10C may perform the equalization operation to the read data yₖ through the outer information and the soft decision value received from one of the other equalizing units.

The plurality of equalizing units 10A, 10B and 10C may receive the read data yₖ read out from the memory apparatus 200.

For removing the interference data from the read data yₖ, the first equalizing unit 10A may remove from the read data yₖ the first interference data group (i.e., the first off-track interference data and the first linear equalization interference data) through the third outer information L_{o,3}(xₖ) and the third soft decision value L₃(xₖ) received from the third equalizing unit 10C. The third outer information L_{o,3}(xₖ) may be a first priori information, and the third soft decision value L₃(xₖ) may be a first priori soft decision value. The first equalizing unit 10A may generate the first outer information L_{o,1}(xₖ) and the first soft decision value L₁(xₖ) through the equalization operation with the first priori information and the first priori soft decision value received from the third equalizing unit 10C, and provide the first outer information L_{o,1}(xₖ) and the first soft decision value L₁(xₖ) to the second equalizing unit 10B. When the first equalizing unit 10A initially performs the equalization operation, an initial value of the first priori information and the first priori soft decision value may be zero (0).

For removing the interference data from the read data yₖ, the second equalizing unit 106 may remove from the read data yₖ the second interference data group (e.g., the second off-track interference data and the second linear equalization interference data) through the first outer information L_{o,1}(xₖ) and the first soft decision value L₁(xₖ) received from the first equalizing unit 10A. The first outer information L_{o,1}(xₖ) may be a second priori information, and the first soft decision value L₁(xₖ) may be a second priori soft decision value. The second equalizing unit 10B may generate the second outer information L_{o,2}(xₖ) and the second soft decision value L₂(xₖ) through the equalization operation with the second priori information and the second priori soft decision value received from the first equalizing unit 10A, and provide the second outer information L_{o,2}(xₖ) and the second soft decision value L₂(xₖ) to the third equalizing unit 10C.

For removing the interference data from the read data yₖ, the third equalizing unit 10C may remove from the read data yₖ the third interference data group (i.e., the third off-track interference data and the third linear equalization interference data) through the second outer information L_{o,2}(xₖ) and the second soft decision value L₂(xₖ) received from the second equalizing unit 10B. The second outer information L_{o,2}(xₖ) may be a third priori information, and the second soft decision value L₂(xₖ) may be a third priori soft decision value. The third equalizing unit 10C may generate the third outer information L_{o,3}(xₖ) and the third soft decision value L₃(xₖ) through the equalization operation with the third priori information and the third priori soft decision value received from the second equalizing unit 10B, and provide the third outer information L_{o,3}(xₖ) and the third soft decision value L₃(xₖ) to the first equalizing unit 10A.

Each of the first to third equalizing units 10A to 10C may repeatedly perform the equalization operations a predetermined number of times or until a stop condition is met. Hereinafter, disclosed will be the first to third equalizing units 10A to 10C repeatedly performing the equalization operations a predetermined number of times.

When the first to third equalizing units 10A to 10C complete the equalization operations a predetermined number of times, the third equalizing unit 10C may provide the third outer information L_{o,3}(xₖ), which is an outcome of the equalization operations, to the decoder 30 without providing the third outer information L_{o,3}(xₖ) to the first equalizing unit 10A. The third outer information L_{o,3}(xₖ) provided to the decoder 30 may be the interference-cancelled data z(xₖ).

When the third equalizing unit 10C provides the interference-cancelled data z(xₖ) not to the decoder 30 but to a threshold value detector (not illustrated) it may not be the third outer information L_{o,3}(xₖ) but the third soft decision value that is the interference-cancelled data z(xₖ).

However, when a predetermined stop condition is met and further subsequent equalization operation is not required during the equalization operation of the first to third equalizing units 10A to 10C, one of the first to third equalizing units 10A to 10C may provide its outer information, which is its outcome of its equalization operation, to the decoder 30 as the interference-cancelled data z(xₖ) without completion of the predetermined number of times of the equalization operation of the first to third equalizing units 10A to 10C. For example, when the predetermined stop condition is met as a result of the equalization operation of the first equalizing unit 10A during repetition of the predetermined number of times of the equalization operation of the first to third equalizing units 10A to 10C, the first equalizing unit 10A may provide the first outer information L_{o,1}(xₖ) to the decoder 30 as the interference-cancelled data z(xₖ).

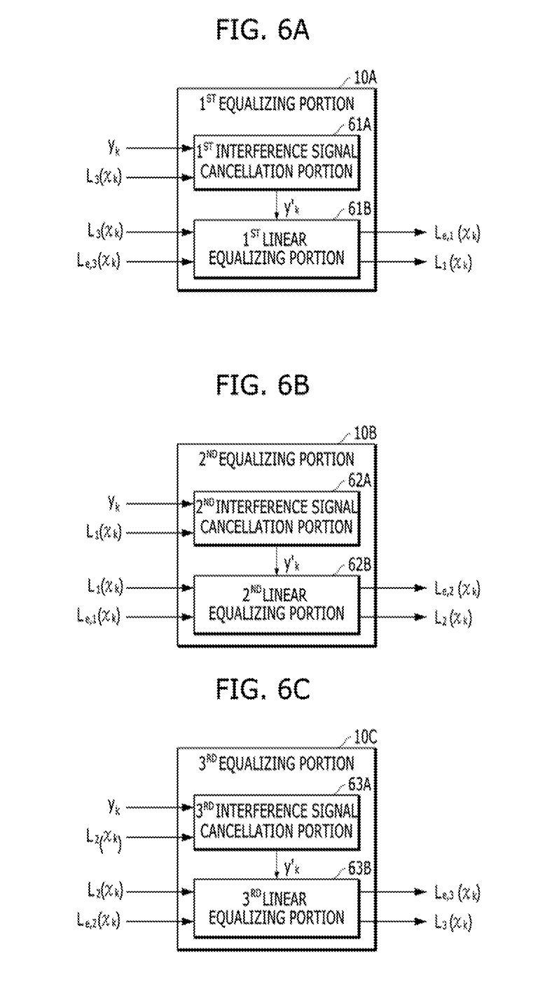

FIG. 6A is a block diagram, schematically illustrating the first equalizing unit 10A shown in FIG. 5, according to an embodiment of the invention.

According to the embodiment of FIG. 6A, the first equalizing unit 10A may include a first interference signal cancellation portion 61A and a first linear equalizing portion 61B.

The first interference signal cancellation portion 61A may remove the first off-track interference data from the read data yₖ through the third soft decision value L₃(xₖ) or the first priori soft decision value. Referring to FIG. 3A, the first off-track interference data may be the plurality of interference data stored in the first, second, fifth and sixth interference memory cells IC1, IC2, IC5 and IC6 of the plurality of first off-track regions OT1.

The interference signal cancellation portion 61A may receive the read data yₖ from the memory apparatus 200, and receive the third soft decision value L₃(xₖ) or the first priori soft decision value from the third equalizing unit 10C. The first priori soft decision value may be the third soft decision value L₃(xₖ) generated by the third equalizing unit 10C. The third soft decision value L₃(xₖ) or the first priori soft decision value may represent the log likelihood ratio (LLR), and may be represented by equation 2 as follows.

$${L}_{3} ( {x}_{k} ) = ln \{ \frac{Pr ( {x}_{k} = + 1 )}{Pr ( {x}_{k} = - 1 )} \} \qquad [ Equation 2 ]$$

In equation 2, denotation “Pr(xₖ=+1)” represents probability that the original data xₖ has a value of “+1”, and denotation “Pr(xₖ=−1)” represents probability that the original data xₖ has a value of “−1”.

The interference signal cancellation portion 61A may generate a first soft information \hat{x}ₖ from the third soft decision value L₃(xₖ) or the first priori soft decision value through the probabilities “Pr(xₖ=+1)” and “Pr(xₖ=−1)”. The first soft information \hat{x}ₖ may be represented by equation 3 as follows.

\hat{x}ₖ=Pr(xₖ=+1)×(+1)+Pr(xₖ=−1)×(−1) [Equation 3]

The first soft information \hat{x}ₖ may represent a function of the log likelihood ratio (LLR). The first interference signal cancellation portion 61A may remove the first off-track interference data from the read data yₖ through the first soft information \hat{x}ₖ and the 2D ISI weight value vector h. The first interference signal cancellation portion 61A may remove the first off-track interference data from the read data yₖ by subtracting, from the read data yₖ, respective multiplication of the first soft information \hat{x}ₖ and 2D ISI weight values hᵢ for the first off-track interference data. The read data yₖ′, which is the read data yₖ minus the first off-track interference data, may be represented by the following equation 4. Hereinafter, the read data yₖ′, which is the read data yₖ minus the first off-track interference data, is referred to as a first off-track-interference-removed data yₖ′.

y′ₖ=yₖ−\hat{x}ₖ₋ₚh₀−\hat{x}ₖ₋ₚ₊₁h₁−\hat{x}ₖ₊ₚ₋₁hₛ−\hat{x}ₖ₊ₚh₆ [Equation 4]

y′ₖ=yₖ−\hat{x}ₖ^{T}h′

In equation 4, denotation \hat{x}ₖ^{T} represents each soft information for the first off-track interference data, and is represented as \hat{x}ₖ^{T}=[\hat{x}ₖ₋ₚ, \hat{x}ₖ₋ₚ₊₁, 0,0,0,\hat{x}ₖ₊ₚ₋₁, \hat{x}ₖ₊ₚ].

In equation 4, denotation h′ represents the 2D ISI weight value vector h, and is represented as h′=[h₀,h₁,h₂,h₃,h₄,h₅,h₆].

The first interference signal cancellation portion 61A may provide the first off-track-interference-removed data yₖ′ to the first linear equalizing portion 61B.

The first linear equalizing portion 61B may perform first linear equalization operation of a single direction (e.g., the first direction or the horizontal direction) to the first off-track-interference-removed data yₖ′ received from the first interference signal cancellation portion 61A through the third outer information L_{o,3}(xₖ) or the first priori information and the third soft decision value L₃(xₖ) or the first priori soft decision value. The first linear equalizing portion 61B may perform the first linear equalization operation to the first off-track-interference-removed data yₖ′ using the third outer information L_{o,3}(xₖ) or the first priori information and the third soft decision value L₂(xₖ) or the first priori soft decision value for removing the first linear equalization interference data stored in the third and fourth interference memory cells IC3 and IC4 of the first linear equalization region LE1 from the first off-track-interference-removed data yₖ′. The first linear equalization operation of a single direction may be the minimum mean-square-error (MMSE) equalization operation using the minimum mean-square-error (MMSE) technique.

The third outer information L_{o,3}(xₖ) or the first priori information may be generated and received from the third equalizing unit 10C.

For performing the first linear equalization operation of a single direction the first linear equalizing portion 61B may generate a first filter coefficient g_{qti}. The first linear equalizing portion 61B may generate the first filter coefficient g_{qti} through the third outer information L_{o,3}(xₖ) or the first priori information and the third soft decision value L₃(xₖ) or the first priori soft decision value. In order to generate the first filter coefficient g_{qti}, the first linear equalizing portion 61B may firstly obtain a first average variance value v̅^{o} through the third soft decision value L₃(xₖ) or the first priori soft decision value. The first linear equalizing portion 61B may firstly obtain the first average variance value v̅^{o} as follows. The first linear equalizing portion 61B may firstly obtain an average value x̅ₖ^{o} of each of the plurality of memory cells. The average value k may be represented by the following equation 5.

$${\overline{x}}_{k}^{o} = \frac{exp ( {L}_{3} ( {x}_{k} ) ) - 1}{exp ( {L}_{3} ( {x}_{k} ) ) + 1} = tanh ( \frac{{L}_{3} ( {x}_{k} )}{2} ) \qquad [ Equation 5 ]$$

Then, the first linear equalizing portion 61B may obtain a variance value vₖ^{o} of each of the plurality of memory cells through the average value x̅ₖ^{o}. The variance value vₖ^{o} may be represented by the following equation 6.

vₖ^{o}=1−|x̅ₗ^{o}|² [Equation 6]

Then, the first linear equalizing portion 61B may obtain the first average variance value v̅^{o} through the variance value vₖ^{o} corresponding to each of the plurality of memory cells. The first average variance value v̅^{o} may be represented by the following equation 7.

$${\overline{v}}^{o} = \frac{1}{M} {\sum }_{k = 0}^{M - 1} {v}_{k}^{o} \qquad [ Equation 7 ]$$

In equation 7, denotation “M” represents a number of total memory cells that the original data xₖ is stored in.

Then the first linear equalizing portion 61B may obtain the second average variance value v̅ through the third outer information L_{o,3}(xₖ) or the first priori information. Then, the first linear equalizing portion 61B may obtain the second average variance value v̅ as follows. The first linear equalizing portion 61B may firstly obtain an average value x̅ₖ of each of the plurality of memory cells. The average value x̅ₖ may be represented by the following equation 8.

$${\overline{x}}_{k} = \frac{exp ( {L}_{e , 3} ( {x}_{k} ) ) - 1}{exp ( {L}_{e , 3} ( {x}_{k} ) ) + 1} = tanh ( \frac{{L}_{e , 3} ( {x}_{k} )}{2} ) \qquad [ Equation 8 ]$$

Then, the first linear equalizing portion 61B may obtain a variance value vₖ of each of the plurality of memory cells through the average value x̅ₖ. The variance value vₖ may be represented by the following equation 9.

vₖ=1−|x̅ₖ|² [Equation 9]

Then, the first linear equalizing portion 61B may obtain a second average variance value v̅ through the variance value vₖ corresponding to each of the plurality of memory cells. The second average variance value v̅ may be represented by the following equation 10.

$$\overline{v} = \frac{1}{M} {\sum }_{k = 0}^{M - 1} {v}_{k} \qquad [ Equation 10 ]$$

The first linear equalizing portion 61B may generate the first filter coefficient g_{qti} through the first average variance value v̅^{o} and the second average variance value v̅. The first filter coefficient g_{qti} may be represented by the following equation 11.

g_{qti}={σₙ²I_{N}+H^{T}R̅ₓₓH+Hₒ^{T}R̅ₓₓ^{o}Hₒ}⁻¹s [Equation 11]

In equation 11, denotation σₙ² represents a variance value of the AWGN and denotation I_{N} represents an identity matrix of a size N.

In equation 11, denotation Hₒ^{T} is represented by

$${H}_{o}^{T} = [ \begin{matrix}{h}_{0} & {h}_{1} & 0 & 0 & {h}_{5} & {h}_{6} & 0 & 0 \\ 0 & {h}_{0} & {h}_{1} & 0 & 0 & {h}_{5} & {h}_{6} & 0 \\ 0 & 0 & {h}_{0} & {h}_{1} & 0 & 0 & {h}_{5} & {h}_{6}\end{matrix} ] .$$

In equation 11, denotation R̅ₓₓ^{o} represents a covariance matrix to the first average variance value v̅^{o} and is represented by R̅ₓₓ^{o}=diag[v̅^{o} . . . v̅^{o}],

In equation 11, denotation H^{T} is represented by

$${H}^{T} = [ \begin{matrix}{h}_{2} & {h}_{3} & {h}_{4} & 0 & 0 \\ 0 & {h}_{2} & {h}_{3} & {h}_{4} & 0 \\ 0 & 0 & {h}_{2} & {h}_{3} & {h}_{4}\end{matrix} ] .$$

In equation 11, denotation R̅ₓₓ represents a covariance matrix to the second average variance value v̅ and is represented by R̅ₓₓ=diag[v̅,v̅,1,v̅,v̅]. In equation 11, denotation “s” is represented by s=H^{T}e and denotation “e” is represented by e=[0,0,1,0,0].

The first linear equalizing portion 61B may obtain the first interference-cancelled data z(xₖ) by performing the first linear equalization operation of a single direction to the first off-track-interference-removed data yₖ′ received from the first interference signal cancellation portion 61A through the first filter coefficient g_{qti}, The first interference-cancelled data z(xₖ) may be represented by the following equation 12.

z(xₖ)=g_{qti}^{T}(′ₖ−H^{T}x̅ₖ+x̅ₖs) [Equation 12]

In equation 12, denotation y′ₖ represents a vector of the first off-track-interference-removed data yₖ′, and is represented by yₖ′=[y′ₖ₋₁,y′ₖ,y′ₖ₊₁]. In equation 12, denotation x̅ₖ represents a vector of the average value x̅ₖ of equation 8, and is represented by x̅ₖ=[x̅ₖ₋₂,x̅ₖ₋₁,x̅ₖ,x̅ₖ₊₁,x̅ₖ₊₂].

The first linear equalizing portion 61B may obtain the first outer information L_{o,1}(xₖ) through the first interference-cancelled data z(xₖ), and obtain the first soft decision value L₁(xₖ) through the first outer information L_{o,1}(xₖ) and the third outer information L_{o,3}(xₖ) or the first priori information. The first outer information L_{o,1}(xₖ) and the first soft decision value L₁(xₖ) may be represented by equation 13 and equation 14, respectively.

$$\begin{matrix}{L}_{e , 1} ( {x}_{k} ) = \frac{2 z ( {x}_{k} )}{1 - {s}^{T} {g}_{qti}} & [ Equation 13 ] \\ {L}_{1} ( {x}_{k} ) = {L}_{e , 1} ( {x}_{k} ) + {L}_{e , 3} ( {x}_{k} ) & [ Equation 14 ]\end{matrix}$$

In equation 13, denotation L_{o,1}(xₖ) represents the first outer information L_{o,1}(x₎. In equation 14, denotation L₁(xₖ) represents the first soft decision value L₁(xₖ).

The first linear equalizing portion 61B may provide the first outer information L_{o,1}(xₖ) and the first soft decision value L₁(xₖ) to the second equalizing unit 10B.

FIG. 6B is a block diagram schematically illustrating the second equalizing unit 10B shown in FIG. 5, according to an embodiment of the invention.

According to the embodiment of FIG. 6B, the second equalizing unit 10B may include a second interference signal cancellation portion 62A and a second linear equalizing portion 62B. The second interference signal cancellation portion 62A and the second linear equalizing portion 62B may be the same as the first interference signal cancellation portion 61A and the first linear equalizing portion 61B, respectively, described with reference to FIG. 6A except for the input and output signals of the second interference signal cancellation portion 62A and the second linear equalizing portion 62B, which will be described hereinafter.

The second interference signal cancellation portion 62A may remove the second off-track interference data from the read data yₖ through the second priori soft decision value L₁(xₖ). Referring to FIG. 3B, the second off-track interference data may be the plurality of interference data stored in the second to fifth interference memory cells IC2 to IC5 of the plurality of second off-track regions OT2. For example, the second off-track interference data may include the second interference data xₖ₋ₚ₊₁, the third interference data xₖ₋₁, the fourth interference data xₖ₊₁, and the fifth interference data xₖ₊ₚ₋₁ respectively stored in the second, third, fourth, and fifth interference memory cells IC2 to IC5, as described with reference to FIG. 3B. The second interference signal cancellation portion 62A may provide the read data yₖ′, which is the read data yₖ minus the second off-track interference data, to the second linear equalizing portion 62B. Hereinafter, the read data yₖ′, which is the read data yₖ minus the second off-track interference data, is referred to as a second off-track-interference-removed data yₖ′.

The second linear equalizing portion 62B may perform a second linear equalization operation of a single direction (e.g., the second direction or the first diagonal direction) to the second off-track-interference-removed data yₖ′ received from the second interference signal cancellation portion 62A through the second priori information L_{o,1}(xₖ) and the second priori soft decision value L₁(xₖ).

For performing the second linear equalization operation of a single direction, the second linear equalizing portion 62B may generate a second filter coefficient. The second linear equalizing portion 62B may generate the second filter coefficient through the second priori information L_{o,1}(xₖ) and the second priori soft decision value L₁(xₖ). The second linear equalizing portion 62B may remove the second linear equalization interference data from the second off-track-interference-removed data yₖ′ received from the second interference signal cancellation portion 62A by performing the second linear equalization operation of a single direction to the second off-track-interference-removed data yₖ′ through the second filter coefficient. The second linear equalizing portion 62B may obtain the second interference-cancelled data z(xₖ) by removing the second linear equalization interference data from the second off-track-interference-removed data yₖ′.

The second linear equalizing portion 62B may obtain the second outer information L_{o,2}(xₖ) through the second interference-cancelled data z(xₖ), and obtain the second soft decision value L₂(xₖ) through the second outer information L_{o,2}(xₖ) and the second priori information L_{o,1}(xₖ).

The second linear equalizing portion 62B may provide the second outer information L_{o,2}(xₖ) and the second soft decision value L₂(xₖ) to the third equalizing unit 10C.

FIG. 6C is a block diagram schematically illustrating the third equalizing unit 10C shown in FIG. 5, according to an embodiment of the invention.

Referring to FIG. 6C, the third equalizing unit 10C may include a third interference signal cancellation portion 63A and a third linear equalizing portion 63B. The third interference signal cancellation portion 63A and the third linear equalizing portion 63B may be the same as the first interference signal cancellation portion 61A and the first linear equalizing portion 61B, respectively, described with reference to FIG. 6A except for the input and output signals of the third interference signal cancellation portion 63A and the third linear equalizing portion 63B, which will be described hereinafter.

The third interference signal cancellation portion 63A may remove the third off-track interference data from the read data yₖ through the third priori soft decision value L₂(xₖ). Referring to FIG. 3C, the third off-track interference data may be the plurality of interference data stored in the first, third, fourth and sixth interference memory cells IC1, IC3, IC4 and IC6 of the plurality of third off-track regions OT3. For example, the third off-track interference data may include the first interference data xₓ₋ₚ, the third interference data xₖ₋₁, the fourth interference data xₖ₋₁, and the sixth interference data xₖ₊ₚ respectively stored in the first third, fourth, and sixth interference memory cells IC1, IC3, IC4 and IC6, as described with reference to FIG. 3C. The third interference signal cancellation portion 63A may provide the read data yₖ′, which is the read data yₖ minus the third off-track interference data, to the third linear equalizing portion 63B. Hereinafter, the read data yₖ′, which is the read data yₖ minus the third off-track interference data, is referred to as a third off-track-interference-removed data yₖ′.

The third linear equalizing portion 63B may perform a third linear equalization operation of a single direction (e.g., the third direction or the second diagonal direction) to the third off-track-interference-removed data yₖ′ received from the third interference signal cancellation portion 63A through the third priori information L_{o,2}(xₖ) and the third priori soft decision value L₂(xₖ).

For performing the third linear equalization operation of a single direction, the third linear equalizing portion 63B may generate a third filter coefficient. The third linear equalizing portion 638 may generate the third filter coefficient through the third priori information L_{o,2}(xₖ) and the third priori soft decision value L₂(xₖ). The third linear equalizing portion 63B may remove the third linear equalization interference data from the third off-track-interference-removed data y^{k}′ received from the third interference signal cancellation portion 63A by performing the third linear equalization operation of a single direction to the third off-track-interference-removed data yₖ′ through the third filter coefficient The third linear equalizing portion 62B may obtain the third interference-cancelled data z(xₖ) by removing the third linear equalization interference data from the third off-track-interference-removed data yₖ′.

The third linear equalizing portion 63B may obtain the third outer information L_{o,3}(xₖ) through the third interference-cancelled data z(xₖ), and obtain the third soft decision value L₃(xₖ) through the third outer information L_{o,3}(xₖ) and the third priori information L_{o,2}(xₖ).

The third linear equalizing portion 638 may provide the third outer information L_{o,3}(xₖ) and the third soft decision value L₃(xₖ) to the first equalizing unit 10A. On the other hand, when the third linear equalizing portion 63B completes the predetermined number of equalization operations or meets the stop condition, the third linear equalizing portion 63B may not provide the third outer information L_{o,3}(xₖ) and the third soft decision value L₃(xₖ) to the first equalizing unit 10A. For example, when the decoder 30 is provided, the third linear equalizing portion 63B may provide the third outer information L_{o,3}(xₖ) to the decoder 30. However, when what is provided is not the decoder 30 but the threshold value detector (not illustrated), the third linear equalizing portion 63B may provide the third outer information L_{o,3}(xₖ) to the threshold value detector (not illustrated).

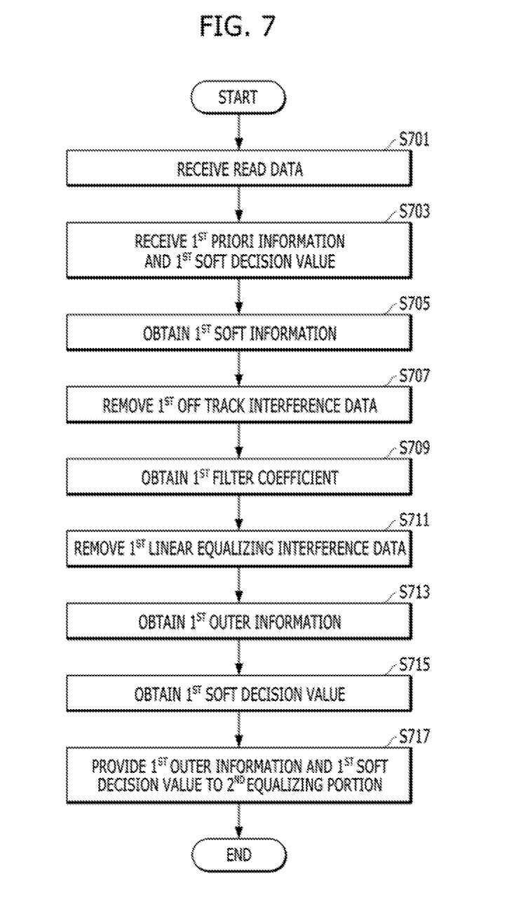

FIG. 7 is a flowchart illustrating an equalization operation of the first equalizing unit 10A, according to an embodiment of the present invention.

According to the embodiment of FIG. 7, the first equalizing unit 10A may receive the read data yₖ from the memory apparatus 200 at step S701.

The first equalizing unit 10A may receive the third outer information L_{o,3}(xₖ) or the first priori information and the third soft decision value L₃(xₖ), or the first priori soft decision value from the third equalizing unit 10C at step S703. The third outer information L_{o,3}(xₖ) may be the first priori information, and the third soft decision value L₃(xₖ) may be the first priori soft decision value.

The first equalizing unit 10A may generate the first soft information \hat{x}ₖ from the third soft decision value L₃(xₖ) or the first priori soft decision value at step S705. The first soft information \hat{x}ₖ may correspond to the first off-track interference data.

The first equalizing unit 10A may remove the first off-track interference data from the read data yₖ through the first soft information \hat{x}ₖ and the 2D ISI weight value vector h at step S707. Referring to FIG. 3A, the first off-track interference data may be the plurality of interference data stored in the first, second, fifth and sixth interference memory cells IC1, IC2, IC5 and IC6 of the plurality of first off-track regions OT1. The read data yₖ′, which is the read data yₖ minus the first off-track interference data, is referred to as the first off-track-interference-removed data yₖ′. The 2D ISI weight value vector h may correspond to the victim memory cell “C” and the interference memory cells IC1 to 106 included in the 2D ISI mask, as described with reference to FIGS. 3A to 3C.

The first equalizing unit 10A may generate the first filter coefficient g_{qti} through the third outer information L_{o,3}(xₖ) or the first priori information and the third soft decision value L₃(xₖ) or the first priori soft decision value at step S709.

The first equalizing unit 10A may remove the first linear equalization interference data stored in the third and fourth interference memory cells IC3 and IC4 of the first linear equalization region LE1 from the first off-track-interference-removed data yₖ′ by performing the first linear equalization operation of a single direction to the first off-track-interference-removed data yₖ′ through the first filter coefficient g_{qti} at step S711.

The first equalizing unit 10A may remove the first linear equalization interference data by performing the first linear equalization operation to the first off-track-interference-removed data yₖ′ through the first filter coefficient g_{qti}. The first off-track-interference-removed data yₖ′, from which the first linear equalization interference data is removed, may be the first interference-cancelled data z(xₖ).

The first equalizing unit 10A may obtain the first outer information L_{o,1}(xₖ) through the first interference-cancelled data z(xₖ) at step S713, and obtain the first soft decision value L₁(xₖ) through the first outer information L_{0,1}(xₖ) and the third outer information L_{o,3}(xₖ) or the first a priori information at step S715.

The first equalizing unit 10A may provide the first outer information L_{o,1}(xₖ) and the first soft decision value L₁(xₖ) to the second equalizing unit 10B at step S717.

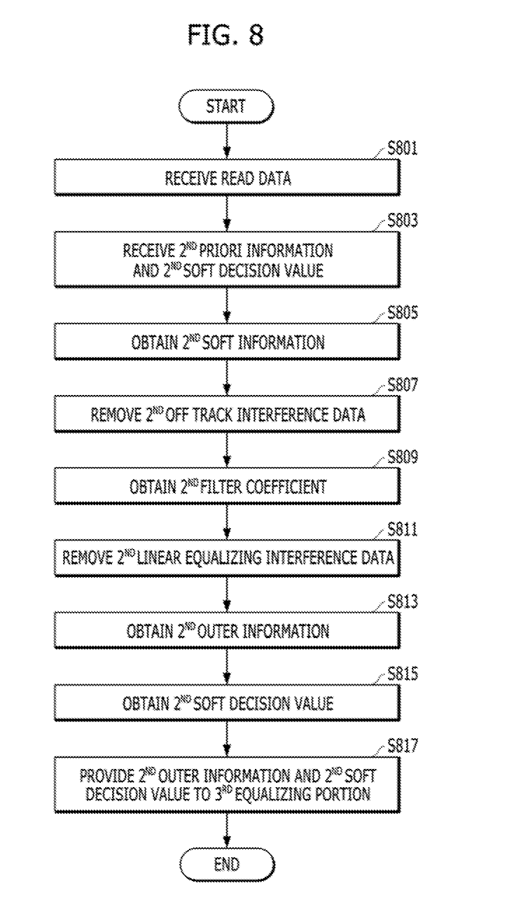

FIG. 8 is a flowchart illustrating an equalization operation of the second equalizing unit 10B, according to an embodiment of the present invention.

Referring to FIG. 8, the second equalizing unit 10B may receive the read data yₖ from the memory apparatus 200 at step S801.

The second equalizing unit 10B may receive the first outer information L_{o,3}(xₖ) or the second priori information and the first soft decision value L₁(xₖ) or the second priori soft decision value from the first equalizing unit 10A at step S803. The first outer information L_{o,1}(xₖ) may be the second priori information, and the first soft decision value L₁(xₖ) may be the second priori soft decision value.

The second equalizing unit 10B may generate the second soft information \hat{x}ₖ from the first soft decision value L₁(xₖ) or the second priori soft decision value at step S805. The second soft information \hat{x}ₖ may correspond to the second off-track interference data.

The second equalizing unit 10B may remove the second off-track interference data from the read data yₖ through the second soft information \hat{x}ₖ and the 2D ISI weight value vector h at step S807. Referring to FIG. 3B, the second off-track interference data may be the plurality of interference data stored in the second to fifth interference memory cells IC2 to IC5 of the plurality of second off-track regions OT2. The read data yₖ′, which is the read data minus the second off-track interference data, is referred to as the second off-track-interference-removed data yₖ′. The 2D ISI weight value vector h may correspond to the victim memory cell and the interference memory cells included in the 2D ISI mask.

The second equalizing unit 10B may generate the second filter coefficient g_{qti} through the first outer information L_{o,1}(xₖ) or the second priori information and the first soft decision value L₁(xₖ) or the second priori soft decision value at step S809.

The second equalizing unit 10B may remove the second linear equalization interference data stored in the first and sixth interference memory cells IC1 to IC6 of the second linear equalization region LE2 from the second off-track-interference-removed data yₖ′ by performing the second linear equalization operation of a single direction to the second off-track-interference-removed data yₖ′ through the second filter coefficient g_{qti} at step S811.

The second equalizing unit 10B may remove the second linear equalization interference data by performing the second linear equalization operation to the second off-track-interference-removed data yₖ′ through the second filter coefficient g_{qti}. The second off-track-interference-removed data yₖ′, from which the second linear equalization interference data is removed, may be the second interference-cancelled data z(xₖ).

The second equalizing unit 10B may obtain the second outer information L_{o,2}(xₖ) through the second interference-cancelled data z(xₖ) step S813 and obtain the second soft decision value L₂(xₖ) through the second outer information L_{o,2}(xₖ) and the first outer information L_{o,1}(xₖ) or the second priori information at step S815.

The second equalizing unit 10B may provide the second outer information L_{o,2}(xₖ) and the second soft decision value L₂(xₖ) to the third equalizing unit 10C at step S817.

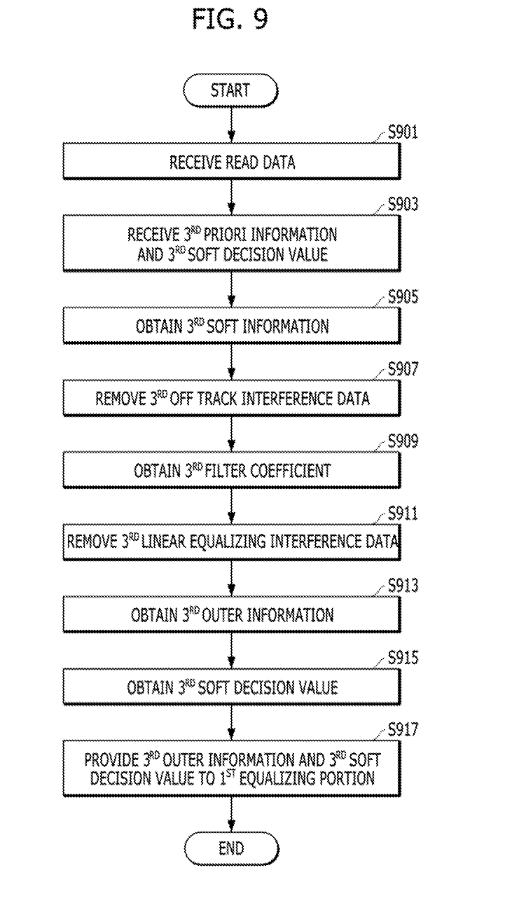

FIG. 9 is a flowchart illustrating an equalization operation of the third equalizing unit 10C according to an embodiment of the present invention.

Referring to FIG. 9, the third equalizing unit 10C may receive the read data yₖ from the memory apparatus 200 at step S901.

The third equalizing unit 10C may receive the second outer information L_{o,2}(xₖ) or the third priori information and the second soft decision value L₂(xₖ) or the third priori soft decision value from the second equalizing unit 10B at step S903. The second outer information L_{o,2}(xₖ) may be the third priori information, and the second soft decision value L₂(xₖ) may be the third priori soft decision value.

The third equalizing unit 10C may generate the third soft information' from from the second soft decision value L₂(xₖ) or the third priori soft decision value at step S905. The third, soft information \hat{x}ₖ may correspond to the third off-track interference data.

The third equalizing unit 10C may remove, the, third off-track interference data from the read data yₖ through the third soft information \hat{x}ₖ and the 2D ISI weight value vector h at step S907. Referring to FIG. 3C, the third off-track interference data may be the plurality of interference data stored in the first, third, fourth and sixth interference memory cells IC1, 1C3, IC4 and IC6 of the plurality of third off-track regions OT3. The read data yₖ′, which is the read data yₖ minus the third off-track interference data, is referred to as the third off-track-interference-removed data yₖ′. The 2D ISI weight value vector h may correspond to the victim memory cell and the interference memory cells included in the 2D ISI mask. The third equalizing unit 10C may generate the third filter coefficient g_{qti} through the second outer information L_{o,2}(xₖ) or the third priori information and the second soft decision value L₂(xₖ) or the third priori soft decision value at step S909.

The third equalizing unit 10C may remove the third linear equalization interference data stored in the second and fifth interference memory cells IC2 and IC5 of the third linear equalization region LE3 from the third off-track-interference-removed data yₖ′ by performing the third linear equalization operation of a single direction to the third off-track-interference-removed data yₖ′ through the third filter coefficient g_{qti} at step S911.

The third equalizing unit 10C may remove the third linear equalization interference data by performing the third linear equalization operation to the third off-track-interference-removed data yₖ′ through the third filter coefficient g_{qti}. The third off-track-interference-removed data yₖ′, from which the third linear equalization interference data is removed, may be the third interference-cancelled data z(xₖ).

The third equalizing unit 10C may obtain the third outer information L_{o,3}(xₖ) through the third interference-cancelled data z(xₖ) at step S913, and obtain the third soft decision value L₃(xₖ) through the third outer information L₃(xₖ) and the second outer information L_{o,2}(xₖ) or the third priori information at step S915.

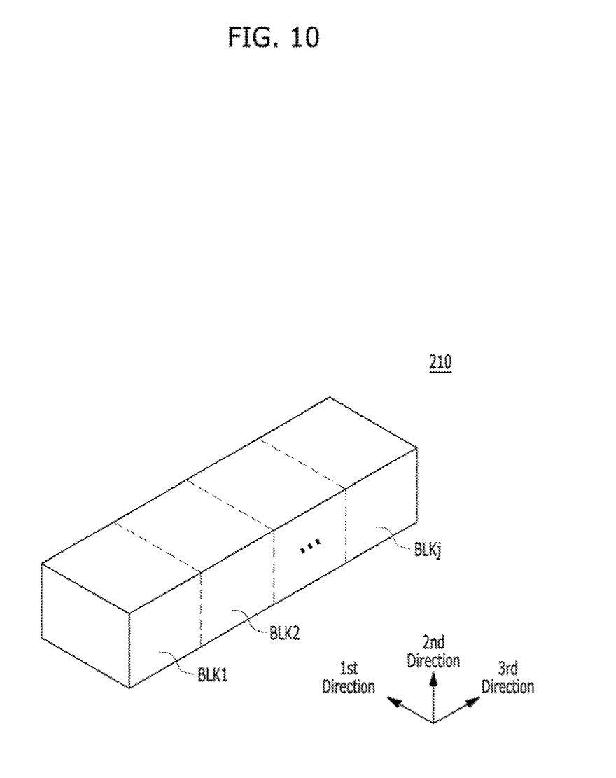

The third equalizing unit 10C may provide the third outer information L_{o,3}(xₖ) and the third soft decision value L₃(xₖ) to the first equalizing unit 10A at step S917 FIGS. 10 to 17 are schematic diagrams illustrating the memory device 150 shown in FIG. 1.

FIG. 10 is a block diagram illustrating an example of the memory blocks 210 of the memory device 200 shown in FIG. 1.

Referring to FIG. 10, the memory blocks 210 of the memory device 200 may include a plurality of memory blocks BLK1 to BLKj. Each of the memory blocks BLK1 to BLKj may have a three-dimensional (3D) structure or vertical structure. For example, each of the memory blocks BLK1 to BLKj may include structures extending in first to third directions for example, an x-axis direction a y-axis direction and a z-axis direction.

Each of the memory blocks BLK1 to BLKj may include a plurality of NAND strings NS extending in the second direction. The plurality of NAND strings NS may be provided in the first direction and the third direction.

The respective NAND strings NS may be electrically coupled to a bit line BL, at least one source select line SSL, at least one ground select line GSL, a plurality of word lines WL, at least one dummy word lines DWL, and a common source line CSL. For example, the respective memory blocks BLK1 to BLKj may be electrically coupled to a plurality of bit lines BL, a plurality of string select lines SSL a plurality of ground select lines GSL, a plurality of word lines WL, a plurality of dummy word lines DWL, and a plurality of common source lines CSL.

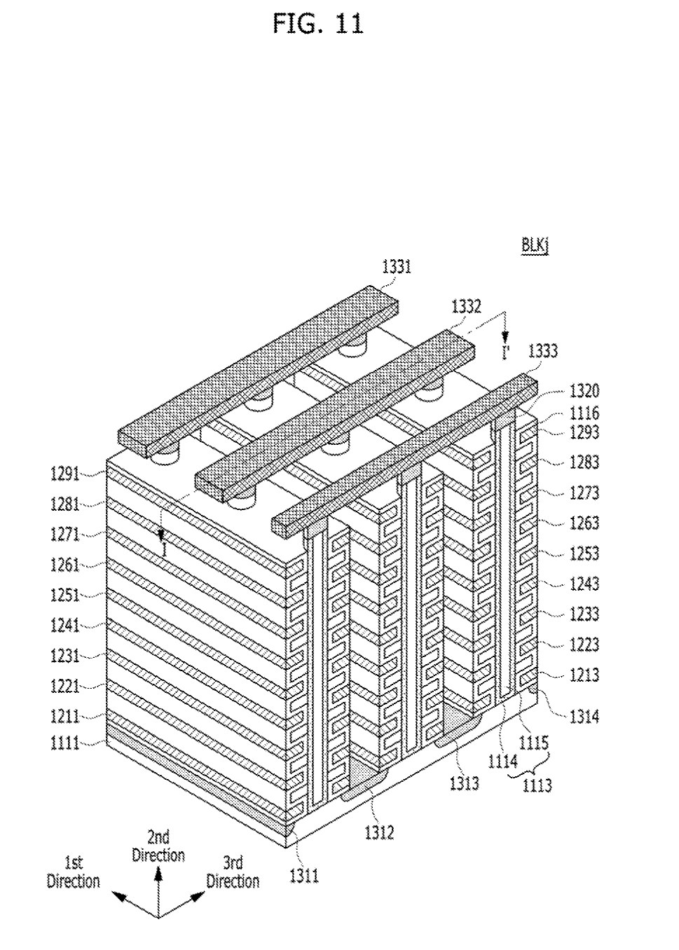

FIG. 11 is a perspective view of one memory block BLKj of the memory blocks BLK1 to BLKj shown in FIG. 10. FIG, 12 is a cross-sectional view taken along a line I-I′ of the memory block BLKj shown in FIG. 11.

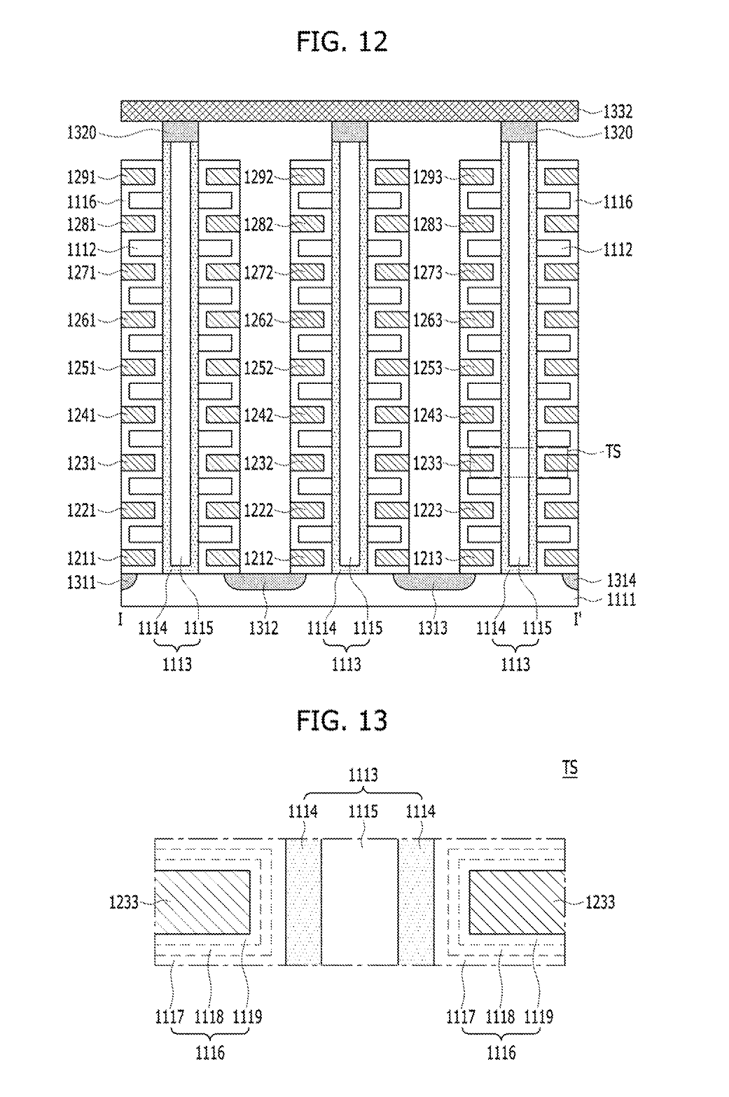

Referring to FIGS. 11 and 12, a memory block BLKj among the plurality of memory blocks 210 of the memory device 200 may include a structure extending in the first to third directions.

A substrate 1111 may be provided. The substrate 1111 may include a silicon material doped by a first type impurity. The substrate 1111 may include a silicon material doped by a p-type impurity or may be a p-type well, for example, a pocket p-well and include an n-type well which surrounds the p-type well. While it is assumed that the substrate 1111 is p-type silicon, it is to be noted that the substrate 11 is not limited to p-type silicon.

A plurality of doping regions 1311 to 1314 extending in the first direction may be provided over the substrate 1111. The plurality of doping regions 1311 to 1314 may contain a second type of impurity that is different from the substrate 1111. The plurality of doping regions 1311 to 1314 may be doped with an n-type impurity. While it is assumed here that first to fourth doping regions 1311 to 1314 are n-type, it is to be noted that the first to fourth doping regions 1311 to 1314 are not limited to being n-type.

In the region over the substrate 1111 between the first and second doping regions 1311 and 1312, a plurality of insulation materials 1112 extending in the first direction may be sequentially provided in the second direction. The insulation materials 1112 and the substrate 1111 may be separated from one another by a predetermined distance in the second direction. The dielectric materials 1112 may be separated from one another by a predetermined distance in the second direction. The dielectric materials 1112 may include a dielectric material such as silicon oxide,

In the region over the substrate 1111 between the first and second doping regions 1311 and 1312, a plurality of pillars 1113 which are sequentially disposed in the first direction and pass through the dielectric materials 1112 in the second direction may be provided. The plurality of pillars 1113 may respectively pass through the dielectric materials 1112 and may be electrically coupled with the substrate 1111. Each pillar 1113 may be configured by a plurality of materials. The surface layer 1114 of each pillar 1113 may include a silicon material doped with the first type of impurity. The surface layer 1114 of each pillar 1113 may include a silicon material doped with the same type of impurity as the substrate 1111. While it assumed here that the surface layer 1114 of each pillar 1113 may include p-type silicon, the surface layer 1114 of each pillar 1113 is not limited to being p-type silicon.

An inner layer 1115 of each of the pillars 1113 may be formed of a dielectric material. The inner layer 1115 of each pillar 1113 may be filled by a dielectric material such as silicon oxide.

In the region between the first and second doping regions 1311 and 1312, a dielectric layer 1116 may be provided along the exposed surfaces of the dielectric materials 1112, the pillars 1113, and the substrate 1111. The thickness of the dielectric layer 1116 may be less than half of the distance between the dielectric materials 1112. For example, a region, in which a material other than the dielectric materials 1112 and the dielectric layer 1116 may be disposed, may be provided between (i) the dielectric layer 1116 provided over the bottom surface of a first dielectric material of the dielectric materials 1112 and (ii) the dielectric layer 1116 provided over the top surface of a second dielectric material of the dielectric materials 1112. The dielectric materials 1112 lie below the first dielectric material.

In the region between the first and second doping regions 1311 and 1312, conductive materials 1211 to 1291 may be provided over the exposed of the dielectric layer 1116. The conductive material 1211 extending in the first direction may be provided between the dielectric material 1112 adjacent to the substrate 1111 and the substrate 5111. In particular, the conductive material 1211 extending, in the first direction may be provided between (i) the dielectric layer 1116 disposed over the substrate 1111 and (ii) the dielectric layer 1116 disposed over the bottom surface of the dielectric material 1112 adjacent to the substrate 1111.

The conductive material extending in the first direction may be provided between (i) the dielectric layer 1116 disposed over the top surface of one of the dielectric materials 1112 and (ii) the dielectric layer 1116 disposed over the bottom surface of another dielectric material of the dielectric materials 1112, which is disposed over the certain dielectric material 1112. The conductive materials 1221 to 1281 extending in the first direction may be provided between the dielectric materials 1112. The conductive material 1291 extending in the first direction may be provided over the uppermost dielectric material 1112. The conductive materials 1211 to 1291 extending in the first direction may be a metallic material. The conductive materials 1211 to 1291 extending in the first direction may be a conductive material such as polysilicon.

In the region between the second and third doping regions 1312 and 1313, the same structures as the structures between the first and second doping regions 1311 and 1312 may be provided. For example, in the region between the second and third doping regions 1312 and 1313 the plurality of insulation materials 1112 extending in the first direction, the plurality of pillars 1113 which are sequentially arranged in the first direction and pass through the plurality of dielectric materials 1112 in the second direction, the dielectric layer 1116 which is provided over the exposed surfaces of the plurality of dielectric materials 1112 and the plurality of pillars 1113, and the plurality of conductive materials 1212 to 1292 extending in the first direction may be provided.

In the region between the third and fourth doping regions 1313 and 1314, the same structure as between the first and second doping regions 1311 and 1312 may be provided. For example, in the region between the third and fourth doping regions 1313 and 1314, the plurality of dielectric materials 1112 extending in the first direction, the plurality of pillars 1113 which are sequentially arranged in the first direction and pass through the plurality of dielectric materials 1112 in the second direction, the dielectric layer 1116 which is provided over the exposed surfaces of the plurality of dielectric materials 1112 and the plurality of pillars 1113, and the plurality of conductive materials 1213 to 1293 extending in the first direction may be provided.

Drains 1320 may be respectively provided over the plurality of pillars 1111. The drains 1320 may be silicon materials doped with second type impurities. The drains 1320 may be silicon materials doped with n-type impurities. While it is assumed for the sake of convenience that the drains 1320 include n-type silicon, it is to be noted that the drains 1320 are not limited to being n-type For example, the width of each drain 1320 may be larger than the width of each corresponding pillars 1113. Each drain 1320 may be provided in the shape of a pad over the top surface of each corresponding pillar 1113.

Conductive materials 1331 to 1333 extending in the third direction may be provided over the drains 1320. The conductive materials 1331 to 1333 may be sequentially disposed in, the first direction. The respective conductive materials 1331 to 1333 may be electrically coupled with the drains 1320 of corresponding regions. The drains 1320 and the conductive materials 1331 to 1333 extending in the third direction may be electrically coupled with through contact plugs. The conductive materials 1331 to 1333 extending in the third direction may be a metallic material. The conductive materials 1331 to 1333 extending in the third direction may be a conductive material such as polysilicon.

Referring to FIGS. 11 and 12, the respective pillars 1113 may form strings together with the dielectric layer 1116 and the conductive materials 1211 to 1291, 1212 to 1292 and 1213 to 1293 extending in the first direction. The respective pillars 1113 may form NAND strings NS together with the dielectric layer 1116 and the conductive materials 1211 to 1291, 1212 to 1292, and 1213 to 1293 extending in the first direction. Each NAND string NS may include a plurality of transistor structures TS.

FIG. 13 is a cross-sectional view of the transistor structure TS shown in FIG. 12.

Referring to FIG,. 13, in the transistor structure TS shown in FIG, 12, the dielectric layer 1116 may include first to third sub dielectric layers 1117, 1118 and 1119.

The surface layer 1114 of p-type silicon in each of the pillars 1113 may serve as a body. The first sub dielectric layer 1117 adjacent to the pillar 1113 may serve as a tunneling dielectric layer, and may include a thermal oxidation layer.

The second sub dielectric layer 1118 may serve as a charge storing layer. The second sub dielectric layer 1118 may serve as a charge capturing layer, and may include a nitride layer or a metal oxide layer such as an aluminum oxide layer, a hafnium oxide layer, or the like.

The third sub dielectric layer 1119 adjacent to the conductive material 1233 may serve as a blocking dielectric layer. The third sub dielectric layer 1119 adjacent to the conductive material 1233 extending in the first direction may be formed as a single layer or multiple layers. The third sub dielectric layer 1119 may be a high-k dielectric layer such as an aluminum oxide layer, a hafnium oxide layer, or the like, which has a dielectric constant greater than the first and second sub dielectric layers 1117 and 1118.

The conductive material 1233 may serve as a gate or a control gate. That is, the gate or the control gate 1233, the blocking dielectric layer 1119, the charge storing layer 1118, the tunneling dielectric layer 1117 and the body 1114 may form a transistor or a memory cell transistor structure. For example, the first to third sub dielectric layers 1117 to 1119 may form an oxide-nitride-oxide (ONO) structure. In the embodiment, for the sake of convenience, the surface layer 1114 of p-type silicon in each of the pillars 1113 will be referred to as a body in the second direction.

The memory block BLKj may include the plurality of pillars 1113. For example, the memory block BLKj may include the plurality of NAND strings NS. In detail, the memory block BLKj may include the plurality of NAND strings NS extending in the second direction or a direction perpendicular to the substrate 1111.

Each NAND string NS may include the plurality of transistor structures TS which are disposed in the second direction. At least one of the plurality of transistor structures TS of each NAND string NS may serve as a string source transistor SST. At least one of the plurality of transistor structures TS of each NAND string NS may serve as a ground select transistor GST.

The gates or control gates may correspond to the conductive materials 1211 to 1291, 1212 to 1292 and 1213 to 1293 extending in the first direction. For example, the gates or the control gates may extend in the first direction and form word lines and at least two select lines, at least one source select line SSL and at least one ground select line GSL.

The conductive materials 1331 to 1333 extending in the third direction may be electrically coupled to one end of the NAND strings NS. The conductive materials 1331 to 1333 extending in the third direction may serve as bit lines BL That is, in one memory block BLKi, the plurality of NAND strings NS may be electrically coupled to one-bit line BL.

The second type doping regions 1311 to 1314 extending in the first direction may be provided to the other ends of the NAND strings NS. The second type doping regions 1311 to 1314 extending in the first direction may serve as common source lines CSL.

For example, the memory block BLKi may include a plurality of NAND strings NS extending in a direction perpendicular to the substrate 1111, e.g., the second direction, and may serve as a NAND flash memory block, for example, of a charge capturing type memory, in which a plurality of NAND strings NS are electrically coupled to one-bit line BL.

While it is illustrated in FIGS. 11 to 13 that the conductive materials 1211 to 1291, 1212 to 1292 and 1213 to 1293 extending in the first direction are provided in 9 layers, it is to be noted that the conductive materials 1211 to 1291, 1212 to 1292 and 1213 to 1293 extending in the first direction are not limited to being provided in 9 layers. For example, conductive materials extending in the first direction may be provided in 8 layers, 16 layers or any multiple of layers. For example, in one NAND string NS, the number of transistors may be 8, 16 or more. While it is illustrated in FIGS. 11 to 13 that 3 NAND strings NS are electrically coupled to one-bit line BL, it is to be noted that the embodiment is not limited to having 3 NAND strings NS that are electrically coupled to one-bit line BL. In the memory block BLKj, m number of NAND strings NS may be electrically coupled to one-bit line BL, m being a positive integer. According to the number of NAND strings NS which are electrically coupled to one-bit line BL, the number of conductive materials 1211 to 1291, 1212 to 1292 and 1213 to 1293 extending in the first direction and the number of common source lines 1311 to 1314 may be controlled as well.

Further, while it is illustrated n FIGS. 11 to 13 that 3 NAND strings NS are electrically coupled to one conductive material extending in the first direction it is to be noted that the embodiment is not limited to having 3 NAND strings NS electrically coupled to one conductive material extending in the first direction. For example, n number of NAND strings NS may be electrically coupled to one conductive material extending in the first direction, n being a positive integer. According to the number of NAND strings NS which are electrically coupled to one conductive material extending in the first direction, the number of bit lines 1331 to 1333 may be controlled as well.

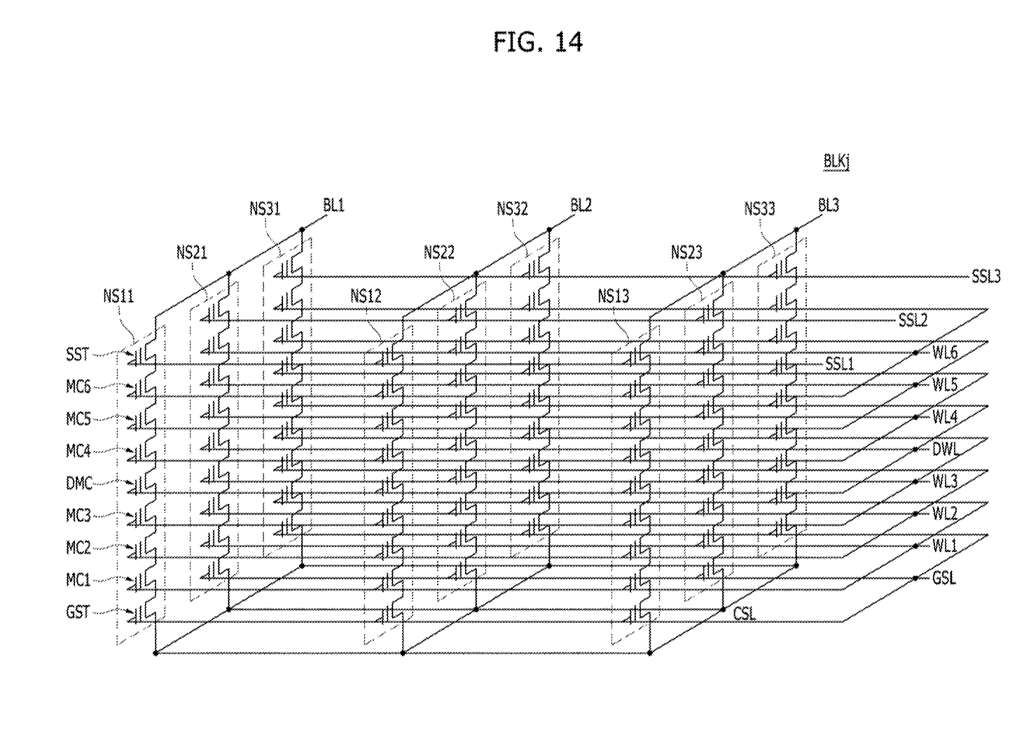

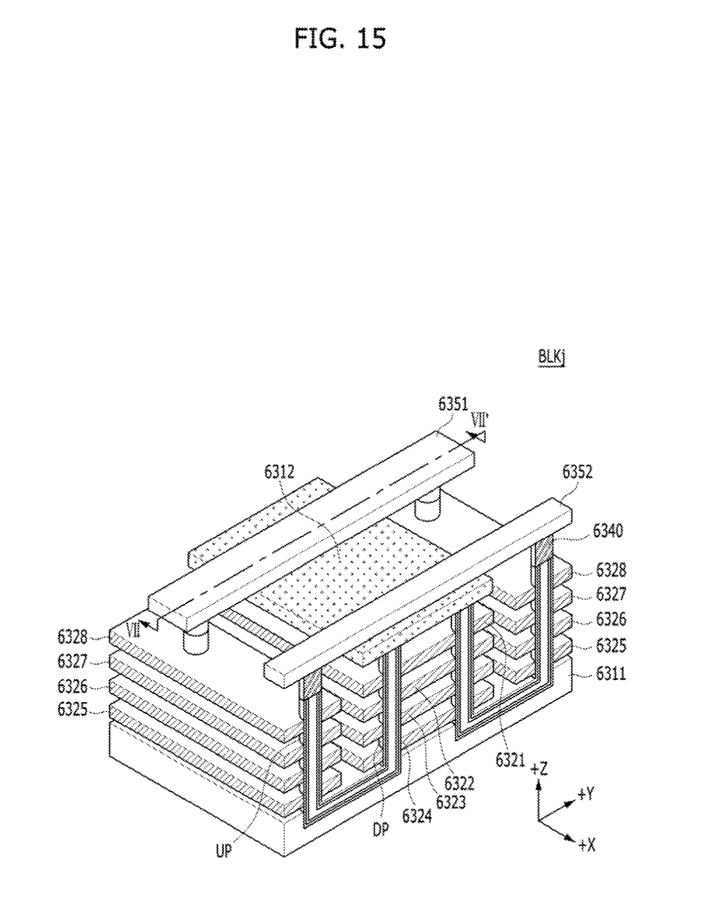

FIG. 14 is an equivalent circuit diagram illustrating the memory block BLKj having a first structure described with reference to FIGS. 11 to 13.

Referring to FIG. 14, in a block BLKj having the first structure, NAND strings NS11 to NS31 may be provided between a first bit line BL1 and a common source line CSL. The first bit line BL1 may correspond to the conductive material 1331 first bit line BL1 may correspond to the conductive material 1332 of FIGS. 11 and 12, extending in the third direction. NAND strings NS12 to NS32 may be provided between a second bit line BL2 and the common source line CSL. The second bit line BL2 may correspond to the conductive material 1332 of FIGS. 11 and 12, extending in the third direction. NAND strings NS13 to NS33 may be provided between a third bit line BL3 and the common source line CSL. The third bit line BL3 may correspond to the conductive material 1333 of FIGS. 11 and 12, extending in the third direction.

A source select transistor SST of each NAND string NS may be electrically coupled to a corresponding bit line BL. A ground select transistor GST of each NAND string NS may be electrically coupled to the common source line CSL. Memory cells MC may be provided between the source select transistor SST and the ground select transistor GST of each NAND string NS.

In this example, NAND strings NS may be defined by units of rows and columns and NAND strings NS which are electrically coupled to one-bit line may form one column. The NAND strings NS11 to NS31 which are electrically coupled to the first bit line BL1 may correspond to a first column, the NAND strings NS12 to NS32 which are electrically coupled to the second bit line BL2 may correspond to a second column, and the NAND strings NS13 to NS33 which are electrically coupled to the third bit line BL3 may correspond to a third column. NAND strings NS which are electrically coupled to one source select line SSL may form one row. The NAND strings NS11 to NS13 which are electrically coupled to a first source select line SSL1 may form a first row, the NAND strings NS21 to NS23 which are electrically coupled to a second source select line SSL2 may form a second row, and the NAND strings NS31 to NS33 which are electrically coupled to a third source select line SSL3 may form a third row.

In each NAND string NS a height may be defined. In each NAND string NS, the height of a memory cell MC1 adjacent to the ground select transistor GST may have a value ‘1’. In each NAND string NS, the height of a memory cell may increase as the memory cell gets closer to the source select transistor SST when measured from the substrate 1111. In each NAND string NS, the height of a memory cell MC6 adjacent to the source select transistor SST may be, for example, 7.

The source select transistors SST of the NAND strings NS in the same row may share the source select line SSL. The source select transistors SST of the NAND strings NS in different rows may be respectively electrically coupled to the different source select lines SSL1 SSL2 and SSL3.

The memory cells at the same height in the NAND strings NS in the same row may share a word line WL. That is, at the same height, the word lines WL may be electrically coupled to the memory cells MC of the NAND strings NS in different rows. Dummy memory cells DMC at the same height in the NAND strings NS of the same row may share a dummy word line DWL. For example, at the same height or level, the dummy word lines DWL may be electrically coupled to the dummy memory cells DMC of the NAND strings NS in different rows.

The word lines WL or the dummy word lines DWL located at the same level or height or layer may be electrically coupled with one another at layers where the conductive materials 1211 to 1291, 1212 to 1292 and 1213 to 1293 extending in the first direction may be provided. The conductive materials 1211 to 1291 1212 to 1292 and 1213 to 1213 extending in the first direction may be electrically coupled in common to upper layers through contacts. At the upper layers the conductive materials 1211 to 1291, 1212 to 1292 and 1213 to 1293 extending in the first direction may be electrically coupled. For example, the ground select transistors GST of the NAND strings NS in the same row may share the ground select line GSL. Further, the ground select transistors GST of the NAND strings NS in different rows may share the ground select line GSL. That is, the NAND strings NS11 to NS13, NS21 to NS23 and NS31 to NS33 may be electrically coupled to the ground select line GSL.

The common source line CSL may be electrically coupled to the NAND strings NS. Over the active regions and over the substrate 1111, the first to fourth doping regions 1311 to 1314 may be electrically coupled. The first to fourth doping regions 1311 to 1314 may be electrically coupled to an upper layer through contacts and, at the upper layer, the first to fourth doping regions 1311 to 1314 may be electrically coupled.

For example, as shown in FIG. 14, the word lines WL of the same height or level may be electrically coupled. Accordingly, when a word line WL at a specific height is selected, all NAND strings NS which are electrically coupled to the word line WL may be selected. The NAND strings NS in different rows may be electrically coupled to different source select lines SSL. Accordingly, among the NAND strings NS electrically coupled to the same word line WL, by selecting one of the source select lines SSL1 to SSL3 the NAND strings NS in the unselected rows may be electrically isolated from the bit lines BL1 to BL3. For example, by selecting one of the source select lines SSL1 to SSL3 a row of NAND strings NS, may be selected. Moreover, by selecting one of the bit lines BL1 to BL3, the NAND strings NS in the selected rows may be selected in units of columns.

In each NAND string NS, a dummy memory cell DMC may be provided. In FIG. 14, the dummy memory cell DMC may be provided between a third memory cell MC3 and a fourth memory cell MC4 in each NAND string NS. That is, first to third memory cells MC1 to MC3 may be provided between the dummy memory cell DMC and the ground select transistor GST. Fourth to sixth memory cells MC4 to MC6 may be provided between the dummy memory cell DMC and the source select transistor SST. The memory cells MC of each NAND string NS may be divided into memory cell groups by the dummy memory cell DMC. In the divided memory cell groups, memory cells, for example, MC1 to MC3, adjacent to the ground select transistor GST may be referred to as a lower memory cell group, and memory cells, for example, MC4 to MC6, adjacent to the string select transistor SST may be referred to as an upper memory cell group.

As described in FIGS. 10 to 14, a semiconductor memory system may include one or more cell strings arranged in a direction perpendicular to a substrate coupled with a memory controller and including memory cells, a string select transistor and a ground select transistor. The semiconductor memory system may operate as follow: (a) may be provided with a first read command to perform first and second hard decision read operations in response to a first hard decision read voltage and a second hard decision read voltage that is different from the first hard decision read voltage; (b) may acquire hard decision data; (c) may select one of the first and second hard decision voltages based on an error bit state of the hard decision data; (d) may acquire soft decision data in response to a soft read voltage that is different from the first and second hard decision read voltages; and (e) may provide the soft decision data to a memory controller.

Hereinbelow, more detailed descriptions will be made with reference to FIGS. 15 to 17, which show the memory device in the memory system according to an embodiment implemented with a three-dimensional (3D) nonvolatile memory device different from the first structure.

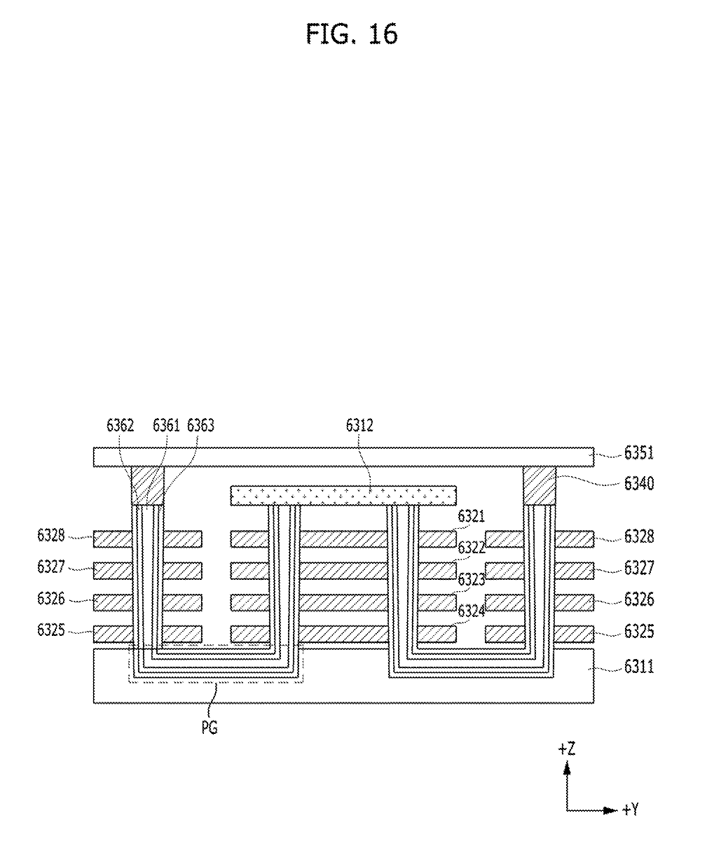

FIG. 15 is a perspective view schematically illustrating the memory device implemented with the three-dimensional (3D) nonvolatile memory device, which is different from the first structure described above with reference to FIGS. 11 to 14, and showing a memory block BLKj of the plurality of memory blocks of FIG. 10. FIG. 16 is a cross-sectional view illustrating the memory block BLKj taken along the line VII-VII′ of FIG. 15.

Referring to FIGS. 15 and 16, the memory block BLKj among the plurality of memory blocks of the memory device 200 of FIG. 1 may include structures extending in the first to third directions.

A substrate 6311 may be provided. For example, the substrate 6311 may include a silicon material doped with a first type impurity. For example, the substrate 6311 may include a silicon material doped with a p-type impurity or may be a p-type well, for example, a pocket p-well, and include an n-type well which surrounds the p-type well. While it is assumed in the embodiment for the sake of convenience that the substrate 6311 is p-type silicon, it is to be noted that the substrate 6311 is not limited to being p-type silicon.

First to fourth conductive materials 6321 to 6324 extending in the x-axis direction and the y-axis direction are provided over the substrate 6311. The first to fourth conductive materials 6321 to 6324 may be separated by a predetermined distance in the z-axis direction.

Fifth to eighth conductive materials 6325 to 6328 extending in the x-axis direction and the y-axis direction may be provided over the substrate 6311. The fifth to eighth conductive materials 6325 to 6328 may be separated by the predetermined distance in the z-axis direction. The fifth to eighth conductive materials 6325 to 6328 may be separated from the first to fourth conductive materials 6321 to 6324 in the y-axis direction.

A plurality of lower pillars DP which pass through the first to fourth conductive materials 6321 to 6324 may be provided. Each lower pillar DP extends in the z-axis direction. Also, a plurality of upper pillars UP which pass through the fifth to eighth conductive materials 6325 to 6328 may be provided. Each upper pillar UP extends in the z-axis direction.

Each of the lower pillars DP and the upper pillars UP may include an internal material 6361, an intermediate layer 6362, and a surface layer 6363. The intermediate layer 6362 may serve as a channel of the cell transistor. The surface layer 6363 may include a blocking dielectric layer, a charge storing layer and a tunneling dielectric layer.

The lower pillar DP and the upper pillar UP may be electrically coupled through a pipe gate PG. The pipe gate PG may be disposed in the substrate 6311. For instance, the pipe gate PG may include the same material as the lower pillar DP and the upper pillar UP.

A doping material 6312 of a second type extending in the x-axis direction and the y-axis direction may be provided over the louver pillars DP. For example, the doping material 6312 of the second type may include an n-type silicon material. The doping material 6312 of the second type may serve as a common source line CSL.

Drains 6340 may be provided over the upper pillars UP. The drains 6340 may include an n-type silicon material. First and second upper conductive materials 6351 and 6352 extending in the y-axis direction may be provided over the drains 6340.

The first and second upper conductive materials 6351 and 6352 may be separated in the x-axis direction. The first and second upper conductive materials 6351 and 6352 may be formed of a metal. The first and second upper conductive materials 6351 and 6352 and the drains 6340 may be electrically coupled through contact plugs. The first and second upper conductive materials 6351 and 6352 respectively serve as first and second bit lines BL1 and BL2.

The first conductive material 6321 may serve as a source select line SSL, the second conductive material 6322 may serve as a first dummy word line DWL1, and the third and fourth conductive materials 6323 and 6324 serve as first and second main word lines MWL1 and MWL2, respectively. The fifth and sixth conductive materials 6325 and 6326 serve as third and fourth main word lines MWL3 and MWL4, respectively, the seventh conductive material 6327 may serve as a second dummy word line DWL2, and the eighth conductive material 6328 may serve as a drain select line DSL.

The lower pillar DP and the first to fourth conductive materials 6321 to 6324 adjacent to the lower pillar DP form a lower string. The upper pillar UP and the fifth to eighth conductive materials 6325 to 6328 adjacent to the upper pillar UP form an upper string. The lower string and the upper string may be electrically coupled through the pipe gate PG. One end of the lower string may be electrically coupled to the doping material 6312 of the second type which serves as the common source line CSL. One end of the upper string may be electrically coupled to a corresponding bit line through the drain 6340. One lower string and one upper string form one cell string which is electrically coupled between the doping material 6312 of the second type serving as the common source line CSL and a corresponding corresponding one of the upper conductive material layers 6351 and 6352 serving as the bit line BL.

That is, the lower string may include a source select transistor SST, the first dummy memory cell DMC1, and the first and second main memory cells MMC1 and MMC2. The upper string may include the third and fourth main memory cells MMC3 and MMC4, the second dummy memory cell DMC2 and a drain select transistor DST.

In FIGS. 15 and 16, the upper string and the lower string may form a NAND string NS, and the NAND string NS may include a plurality of transistor structures TS. Since the transistor structure included in the NAND string NS in FIGS. 15 and 16 is described above in detail with reference to FIG. 13, a detailed description thereof will be omitted herein.

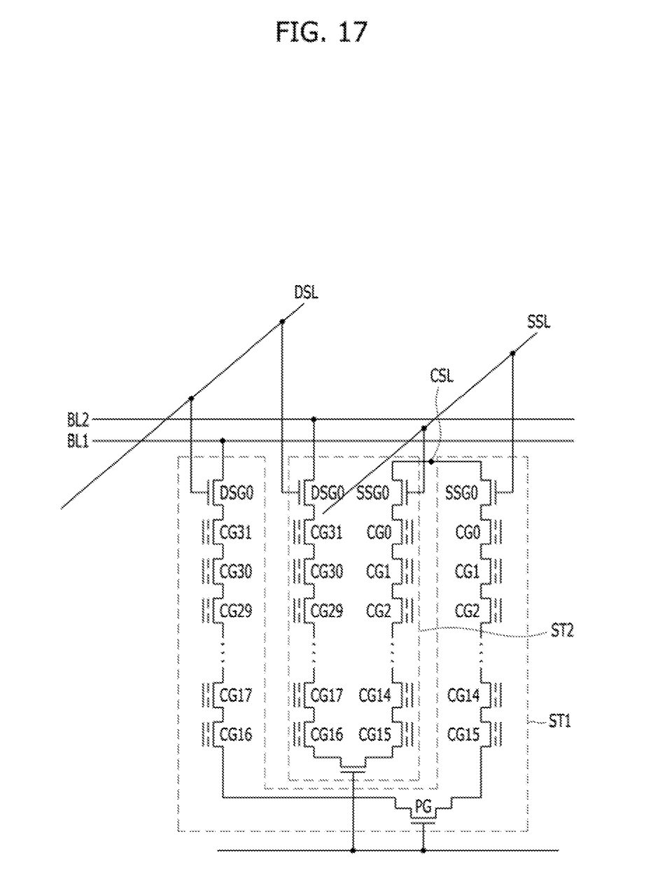

FIG. 17 is a circuit diagram illustrating an equivalent'circuit of the memory block BLKj having the second structure as described above with reference to FIGS. 15 and 16. For the sake of convenience, only a first string and a second string, which form a pair in the memory block BLKj in the second structure are shown.

Referring to FIG. 17 in the memory block BLKj having the second structure among the plurality of blocks of the memory device 150, cell strings, each of which is implemented with one upper string and one lower string electrically coupled through the pipe gate PG as described above with reference to FIGS. 15 and 16, may be provided in such a way as to define a plurality of pairs.

For example, in the certain memory block BLKj having the second structure, memory cells CG0 to CG31 stacked along a first channel CH1 (not shown), for example, at least one source select gate SSG1 and at least one drain select gate DSG1 may form a first string ST1 and memory cells CG0 to CG31 stacked along a second channel CH2 (not shown), for example, at least one source select gate SSG2 and at least one drain select gate DSG2 may form a second string ST2.

The first string ST1 and the second string ST2 may be electrically coupled to the same drain select line DSL and the same source select line SSL. The first string ST1 may be electrically coupled to a first bit line BL1, and the second string ST2 may be electrically coupled to a second bit line BL2.

While it is described in FIG. 17 that the first string ST1 and the second string ST2 are electrically coupled to the same drain select line DSL and the same source select line SSL, it may be envisaged that the first string ST1 and the second string ST2 may be electrically coupled to the same source select line SSL and the same bit line BL, the first string ST1 may be electrically coupled to a first drain select line DSL1 and the second string ST2 may be electrically coupled to a second drain select line DSL2. Further it may be envisaged that the first string ST1 and the second string ST2 may be electrically coupled to the same drain select line DSL and the same bit line BL, the first string ST1 may be electrically coupled to a first source select line SSL1 and the second string ST2 may be electrically coupled a second source select line SSL2.

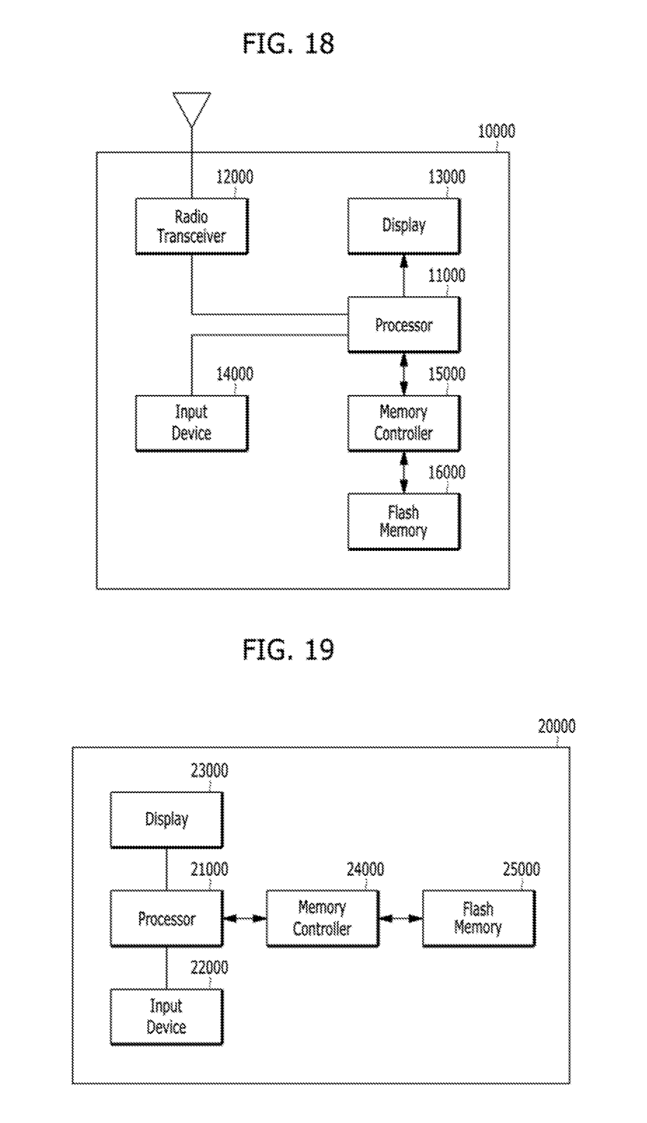

FIG. 18 is a block diagram schematically illustrating an electronic device 10000 including a memory controller 15000 and a flash memory 16000, according to an embodiment of the present invention.

Referring to FIG. 18, the electronic device 10000, may be or include, for example, a cellular phone, a smart phone, or a tablet PC. The electronic device 10000, may include the flash memory 16000 implemented, for example, by a flash memory device and the memory controller 15000 for controlling the flash memory 16000. The flash memory 16000 may correspond to the memory system 110 described above with reference to FIGS. 11 to 18. The flash memory 16000 may store random data. The memory controller 15000 may be controlled by a processor 11000 which controls the overall operations of the electronic device 10000.

Data stored in the flash memory 16000 may be displayed through a display 13000 under the control of the memory controller 15000. The memory controller 15000 may operate under the control of the processor 11000.

A radio transceiver 12000 may receive and transmit a radio signal through an antenna (ANT). For example, the radio transceiver 12000 may convert the radio signal received from the antenna into a signal which will be processed by the processor 11000. Thus, the processor 11000 may process the signal converted by the radio transceiver 12000, and may store the processed signal at the flash memory 16000. Otherwise, the processor 11000 may display the processed signal through the display 13000.

The radio transceiver 12000 may convert a signal from the processor 11000 into a radio signal, and may transmit the converted radio signal externally through the antenna.

An input device 14000 may receive a control signal for controlling an operation of the processor 11000 or data to be processed by the processor 11000. The input device 14000 may be implemented by a pointing device such as, for example, a touch pad, a computer mouse, a key pad, and a keyboard.

The processor 11000 may control the display 13000 so that data from the flash memory 16000, the radio signal from the radio transceiver 12000, or the data from the input device 14000 is displayed through the display 13000.

FIG. 19 is a block diagram schematically illustrating an electronic device 20000 including a memory controller 24000 and a flash memory 25000, according to an embodiment of the present invention.

Referring to FIG. 19, the electronic device 20000 may be implemented by a data processing device, such as, for example, a personal computer (PC), a tablet computer, a net-book, an e-reader, a personal digital assistant (PDA), a portable multimedia player (PMP), an MP3 player, and an MP4 player, and may include the flash memory 25000, for example, the flash memory device, and the memory controller 24000 to control an operation of the flash memory 25000.

The electronic device 20000 may include a processor 21000 to control overall operations of the electronic device 20000. The memory controller 24000 may be controlled by the processor 21000.

The processor 21000 may display data stored in the semiconductor memory system through a display 23000 in response to an input signal from an input device 22000. For example, the input device 22000 may be implemented by a pointing device, such as, for example, a touch pad, a computer mouse, a key pad, and a keyboard.

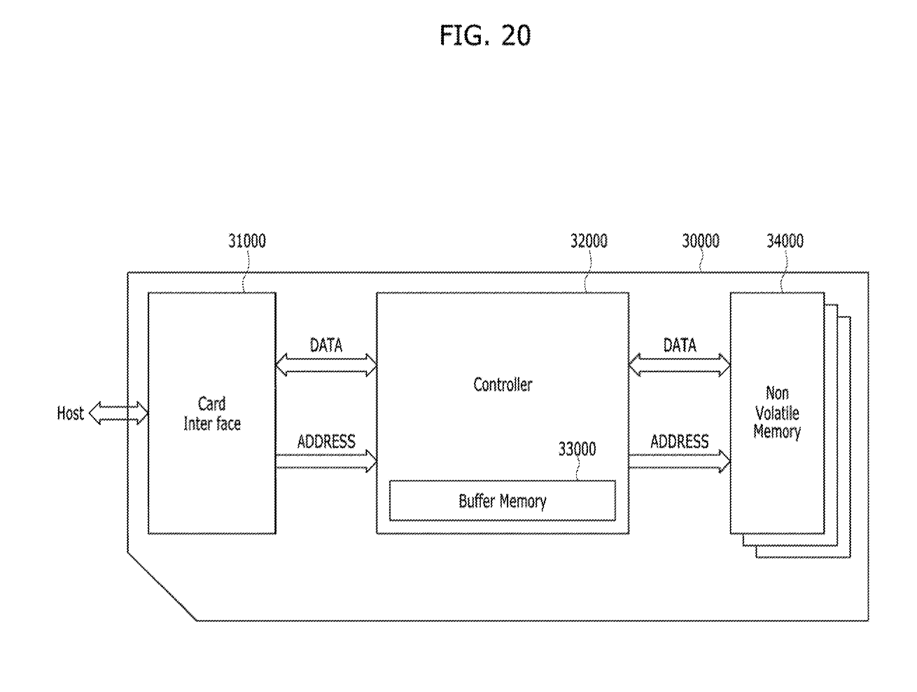

FIG. 20 is a block diagram schematically illustrating an electronic device 30000 including a controller 32000 and a non-volatile memory 34000, according to an embodiment of the present invention.

Referring to FIG. 20, the electronic device 30000 may include a card interface 31000, the controller 32000 and the non-volatile memory 34000, for example, a flash memory device.

The electronic device 30000 may exchange data with a host through the card interface 31000. The card interface 31000 may be or include, for example, a secure digital (SD) card interface, a multi-media card (MMC) interface and the like. The card interface 31000 may interface the host and the controller 32000 according to a communication protocol of the host that is capable of communicating with the electronic device 30000.

The controller 32000 may control the overall operations of the electronic device 30000, and may control data exchange between the card interface 31000 and the non-volatile memory 34000. A buffer memory 33000 of the controller 32000 may buffer data transferred between the card interface 31000 and the non-volatile memory 34000.

The controller 32000 may be coupled with the card interface 31000 and the non-volatile memory 34000 through a data bus DATA and an address bus ADDRESS. According to an embodiment, the controller 32000 may receive an address of data, which is to be read or written, from the card interface 31000 through the address bus ADDRESS, and may send it to the semiconductor memory system 34000. Further, the controller 32000 may receive or transfer data to be read or written through the data bus DATA connected with the card interface 31000 or the semiconductor memory system 34000.

When the electronic device 30000 is connected with the host such as, for example, a PC, a tablet. PC, a digital camera, a digital audio player, a mobile phone, console video game hardware, and a digital set-top box, the host may exchange data with the non-volatile memory 34000 through the card interface 31000 and the controller 32000.

While the present invention has been described with respect to specific embodiments, the embodiments are not intended to be restrictive. The present invention may be achieved in various other ways by those skilled in the art without departing from the spirit and/or scope of the present invention as defined by the following claims.

What is claimed is:

1. A memory system comprising:
a memory apparatus suitable for providing read data; and
a plurality of equalizing units respectively suitable for performing an equalization operation to the read data in a plurality of different directions in a two-dimensional inter-symbol interference (2D ISI) mask,
wherein the 2D ISI mask comprises the read data of a victim cell and a plurality of interference data of interference cells neighboring the victim cell, which exert interferential influence on the read data of the victim cell.

2. The memory system of claim 1, wherein the plurality of equalizing units perform an equalization operation to the read data in a rotational manner.

3. The memory system of claim 1
wherein a first one of the equalizing units generates a first equalization information by performing the equalization operation to the read data in a first direction among the plurality of different directions based on a third equalization information received from a third equalizing unit, and provides the generated first equalization information to a second equalizing unit.

4. The memory system of claim 3,
wherein the first equalizing unit outputs an off-track-interference-removed data by removing an off-track interference data from the read data based on the third equalization information, and
the off-track interference data are the interference data of the interference cells disposed aside from the first direction.

5. The memory system of claim 4,
wherein the first equalizing unit generates the first equalization information by removing a linear equalization interference data from the off-track-interference-removed data based on the third equalization information, and
wherein the linear equalization interference data are the interference data of the interference cells disposed in line with the first direction.

6. The memory system of claim 3,
wherein an equalization information of each of the equalizing units includes an equalized data of the read data, and
further comprising a decoder suitable for performing a decoding operation to the equalized data received from last one of the equalizing units, which lastly performs the equalization operation to the read data.

7. The memory system of claim 3,
wherein an equalization information of each of the equalizing units includes a priori information and a priori soft decision value, and
wherein the priori information is an equalized data of the read data.

8. The memory system of claim 7,
wherein the first equalizing unit outputs an off-track-interference-removed data by removing an off-track interference data from the read data based on the priori soft decision value included in the third equalization information, and
wherein the off-track interference data are the interference data of the interference cells disposed aside from the first direction.

9. The memory system of claim 8,
wherein the first equalizing unit generates the priori information and the priori soft decision value of the first, equalization information by removing a linear equalization interference data from the off-track-interference-removed data based on the priori information and the priori soft decision value included the third equalization information, and
wherein the linear equalization interference data are the interference data of the interference cells disposed in line with the first direction.

10. The memory system of claim 3, wherein the different directions include a horizontal direction, a first diagonal direction, and a second diagonal direction vertically or horizontally reversed to the first diagonal direction.

11. An operation method of a memory system including a memory apparatus, the operation method comprising:
receiving read data from the memory apparatus; and
rotationally performing at least first to third equalization operations to the read data in different directions in a two-dimensional inter-symbol interference (2D ISI) mask,
wherein the 2D ISI mask comprises the read data of a victim cell and a plurality of interference data, which exert interferential influence on the read data of interference cells neighboring the victim cell,
wherein the first equalization operation is performed in a first one of the different directions based on a third equalization information generated by the performing of the third equalization operation thereby generating a first equalization information, and
wherein the generated first equalization information by the performing of the first equalization operation is used in the performing of the second equalization operation.

12. The operation method of claim 11,
wherein the performing of the first equalization operation includes outputting an off-track-interference-removed data by removing an off-track interference data from the read data based on the third equalization information, and
wherein the off-track interference data are the interference data of the interference cells disposed aside from the first direction.

13. The operation method of claim 12,
wherein the first equalization operation includes generating the first equalization information by removing a linear equalization interference data from the off-track-interference-removed data based on the third equalization information, and
wherein the linear equalization interference data are the interference data of the interference cells disposed in line with the first direction.

14. The operation method of claim 11,
wherein an equalization information as a result of each of the at least first to third equalization operations includes an equalized data of the read data, and
further comprising performing a decoding operation to the equalized data, which is a result of last one of the at least first to third equalization operation, which is lastly performed to the read data.

15. The operation method of claim 11,
wherein an equalization information as a result of each of the at least first to third equalization operations includes a priori information and a priori soft decision value, and
wherein the priori information is an equalized data of the read data.

16. The operation method of claim 15,
wherein the performing of the first equalization operation includes outputting an off-track-interference-removed data by removing an off-track interference data from the read data based on the priori soft decision value included in the third equalization information, and
wherein the off-track interference data are the interference data of the interference cells disposed aside from the first direction.

17. The operation method of claim 16,
wherein the first equalization operation includes generating the first equalization information by removing a linear equalization interference data from the off-track-interference-removed data based on the priori information and the priori soft decision value included the third equalization information, and
wherein the linear equalization interference data are the interference data of the interference cells disposed in line with the first direction.

18. The operation method of claim 11, wherein the different directions include a horizontal direction, a first diagonal direction, and a second diagonal direction vertically or horizontally reversed to the first diagonal direction.

19. A memory system; comprising:
a memory apparatus suitable for storing read data and write data requested by a host; and
a controller suitable for providing the read data to the host and providing the write data to the memory apparatus in response to a request of the host, and including a plurality of equalizing units including:
a first equalizing unit suitable for outputting a first data by performing a first equalization operation to the read data provided from the memory apparatus in response to a read command provided from the host,
a second equalizing unit suitable for outputting a second data by performing a second equalization operation to the read data, and
a third equalizing unit suitable for outputting a third data by performing a third equalization operation to the read data.
